(19) United States
(12) Patent Application Publication
(10) Pub. No.: US 2025/0093471 A1
(43) Pub. Date: Mar. 20, 2025

(54) WAVELENGTH STABILITY OF MULTIJUNCTION DIODE LASER IN LIDAR

(71) Applicant: Innovusion, Inc., Sunnyvale, CA (US)

(72) Inventor: Yimin Li, Cupertino, CA (US)

(73) Assignee: Innovusion, Inc., Sunnyvale, CA (US)

(21) Appl. No.: 18/370,224

(22) Filed: Sep. 19, 2023

Related U.S. Application Data
(60) Provisional application No. 63/412,268, filed on Sep. 30, 2022.

(51) Int. Cl. G01S 7/481; G01S 17/931

(52) U.S. Cl. CPC G01S 7/4814; G01S 7/4817; G01S 17/931

(57) ABSTRACT

A system for reducing or eliminating wavelength variations of laser light is provided. The system comprises a semiconductor-based laser source emitting laser light, an optical scanner, and one or more optical elements disposed between the laser source and the optical scanner. The optical scanner is configured to direct the laser light to a field-of-view. The one or more optical elements are configured to direct the laser light from the laser source to the optical scanner. The system further comprises a grating structure mounted to, or integrated with, an optical element of the one or more optical elements. One or more characteristics of the grating structure are configured to reduce or eliminate wavelength variations of the laser light caused by variations of one or more operational conditions of the laser source.

### CROSS-REFERENCE TO RELATED APPLICATIONS

This application claims priority to U.S. Provisional Patent Application Ser. No. 63/412,268, filed Sep. 30, 2022, entitled “WAVELENGTH STABILITY OF MULTIJUNCTION DIODE LASER IN LIDAR”, the content of which is hereby incorporated by reference in its entirety for all purposes.

### FIELD OF THE TECHNOLOGY

This disclosure relates generally to light transmitting and, more particularly, to a system for providing laser light having reduced or eliminated wavelength variations.

### BACKGROUND

Light detection and ranging (LiDAR) systems use light pulses to create an image or point cloud of the external environment. A LiDAR system may be a scanning or non-scanning system. Some typical scanning LiDAR systems include a light source, a light transmitter, a light steering system, and a light detector. The light source generates a light beam that is directed by the light steering system in particular directions when being transmitted from the LiDAR system. When a transmitted light beam is scattered or reflected by an object, a portion of the scattered or reflected light returns to the LiDAR system to form a return light pulse. The light detector detects the return light pulse. Using the difference between the time that the return light pulse is detected and the time that a corresponding light pulse in the light beam is transmitted, the LiDAR system can determine the distance to the object based on the speed of light. This technique of determining the distance is referred to as the time-of-flight (ToF) technique. The light steering system can direct light beams along different paths to allow the LiDAR system to scan the surrounding environment and produce images or point clouds. A typical non-scanning LiDAR system illuminates an entire field-of-view (FOV) rather than scanning through the FOV. An example of the non-scanning LiDAR system is a flash LiDAR, which can also use the ToF technique to measure the distance to an object. LiDAR systems can also use techniques other than time-of-flight and scanning to measure the surrounding environment.

### SUMMARY

Embodiments provided in this disclosure use grating optics for providing spectral selective feedback to semiconductor-based laser sources to improve wavelength stability of the laser sources in LiDAR systems.

In one embodiment, a system for reducing or eliminating wavelength variations of laser light is provided. The system comprises a semiconductor-based laser source emitting laser light, an optical scanner, and one or more optical elements disposed between the laser source and the optical scanner. The optical scanner is configured to direct the laser light to a FOV. The one or more optical elements are configured to direct the laser light from the laser source to the optical scanner. The system further comprises a grating structure mounted to, or integrated with, an optical element of the one or more optical elements. One or more characteristics of the grating structure are configured to reduce or eliminate wavelength variations of the laser light caused by variations of one or more operational conditions of the laser source.

In one embodiment, a LiDAR system comprising a system for reducing or eliminating wavelength variations of laser light is provided. The system comprises a semiconductor-based laser source emitting laser light, an optical scanner, and one or more optical elements disposed between the laser source and the optical scanner. The optical scanner is configured to direct the laser light to a FOV. The one or more optical elements are configured to direct the laser light from the laser source to the optical scanner. The system further comprises a grating structure mounted to, or integrated with, an optical element of the one or more optical elements. One or more characteristics of the grating structure are configured to reduce or eliminate wavelength variations of the laser light caused by variations of one or more operational conditions of the laser source.

In one embodiment, a vehicle comprising a light detection and ranging (LiDAR) system is provided. The LiDAR system comprises a system for reducing or eliminating wavelength variations of laser light is provided. The system comprises a semiconductor-based laser source, an optical scanner, and one or more optical elements disposed between the laser source and the optical scanner. The semiconductor-based laser source is configured to emit laser light. The optical scanner is configured to direct the laser light to a FOV. The one or more optical elements are configured to direct the laser light from the laser source to the optical scanner. The system further comprises a grating structure mounted to, or integrated with, an optical element of the one or more optical elements. One or more characteristics of the grating structure are configured to reduce or eliminate wavelength variations of the laser light caused by variations of one or more operational conditions of the laser source.

### BRIEF DESCRIPTION OF THE DRAWINGS

The present application can be best understood by reference to the embodiments described below taken in conjunction with the accompanying drawing figures, in which like parts may be referred to by like numerals.

FIG. 1 illustrates one or more example LiDAR systems disposed or included in a motor vehicle.

FIG. 2 is a block diagram illustrating interactions between an example LiDAR system and multiple other systems including a vehicle perception and planning system.

FIG. 3 is a block diagram illustrating an example LiDAR system.

FIG. 4 is a block diagram illustrating an example fiber-based laser source.

FIGS. 5A-5C illustrate an example LiDAR system using pulse signals to measure distances to objects disposed in a field-of-view (FOV).

FIG. 6 is a block diagram illustrating an example apparatus used to implement systems, apparatus, and methods in various embodiments.

FIG. 7 is a block diagram illustrating an exemplary system for providing reduced or eliminated wavelength variations of laser light according to an embodiment.

FIGS. 8A-8G are diagrams illustrating examples of grating optics and light paths associated with the grating optics according to some embodiments.

FIGS. 9A and 9B are diagrams illustrating examples of a system comprising a compound cavity formed by an internal cavity of the laser source and a grating structure according to some embodiments.

### DETAILED DESCRIPTION

To provide a more thorough understanding of various embodiments of the present invention, the following description sets forth numerous specific details, such as specific configurations, parameters, examples, and the like. It should be recognized, however, that such description is not intended as a limitation on the scope of the present invention but is intended to provide a better description of the exemplary embodiments.

Throughout the specification and claims, the following terms take the meanings explicitly associated herein, unless the context clearly dictates otherwise:

The phrase “in one embodiment” as used herein does not necessarily refer to the same embodiment, though it may. Thus, as described below, various embodiments of the disclosure may be readily combined, without departing from the scope or spirit of the invention.

As used herein, the term “or” is an inclusive “or” operator and is equivalent to the term “and/or,” unless the context clearly dictates otherwise.

The term “based on” is not exclusive and allows for being based on additional factors not described unless the context clearly dictates otherwise.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously. Within the context of a networked environment where two or more components or devices are able to exchange data, the terms “coupled to” and “coupled with” are also used to mean “communicatively coupled with”, possibly via one or more intermediary devices. The components or devices can be optical, mechanical, and/or electrical devices.

Although the following description uses terms “first,” “second,” etc. to describe various elements, these elements should not be limited by the terms. These terms are only used to distinguish one element from another. For example, a first sensor could be termed a second sensor and, similarly, a second sensor could be termed a first sensor, without departing from the scope of the various described examples. The first sensor and the second sensor can both be sensors and, in some cases, can be separate and different sensors.

In addition, throughout the specification, the meaning of “a”, “an”, and “the” includes plural references, and the meaning of “in” includes “in” and “on”.

Although some of the various embodiments presented herein constitute a single combination of inventive elements, it should be appreciated that the inventive subject matter is considered to include all possible combinations of the disclosed elements. As such, if one embodiment comprises elements A, B, and C, and another embodiment comprises elements B and D, then the inventive subject matter is also considered to include other remaining combinations of A, B, C, or D, even if not explicitly discussed herein. Further, the transitional term “comprising” means to have as parts or members, or to be those parts or members. As used herein, the transitional term “comprising” is inclusive or open-ended and does not exclude additional, unrecited elements or method steps.

As used in the description herein and throughout the claims that follow, when a system, engine, server, device, module, or other computing element is described as being configured to perform or execute functions on data in a memory, the meaning of “configured to” or “programmed to” is defined as one or more processors or cores of the computing element being programmed by a set of software instructions stored in the memory of the computing element to execute the set of functions on target data or data objects stored in the memory.

It should be noted that any language directed to a computer should be read to include any suitable combination of computing devices or network platforms, including servers, interfaces, systems, databases, agents, peers, engines, controllers, modules, or other types of computing devices operating individually or collectively. One should appreciate the computing devices comprise a processor configured to execute software instructions stored on a tangible, non-transitory computer readable storage medium (e.g., hard drive, FPGA, PLA, solid state drive, RAM, flash, ROM, or any other volatile or non-volatile storage devices). The software instructions configure or program the computing device to provide the roles, responsibilities, or other functionality as discussed below with respect to the disclosed apparatus. Further, the disclosed technologies can be embodied as a computer program product that includes a non-transitory computer readable medium storing the software instructions that causes a processor to execute the disclosed steps associated with implementations of computer-based algorithms, processes, methods, or other instructions. In some embodiments, the various servers, systems, databases, or interfaces exchange data using standardized protocols or algorithms, possibly based on HTTP, HTTPS, AES, public-private key exchanges, web service APIs, known financial transaction protocols, or other electronic information exchanging methods. Data exchanges among devices can be conducted over a packet-switched network, the Internet, LAN, WAN, VPN, or other type of packet switched network; a circuit switched network; cell switched network; or other type of network.

A laser source is an essential component of a LiDAR system. Compared with fiber-based lasers, semiconductor-based lasers have advantages in size, efficiency, and cost. For example, a broad area multi-junction diode laser is widely used in many near-infrared (NIR) LiDAR systems. A new type of Vertical-cavity surface-emitting laser (VCSEL) diode laser also shows great potential. A semiconductor-based laser can provide more power than needed in a LiDAR system (e.g., using a large number of diodes collectively). For instance, a semiconductor-based laser can be configured to emit laser light have a sufficiently high intensity such that a single photon return light formed based on the emitted laser light has enough power, which is above the detection limitation of a detector. However, a semiconductor-based laser used in the LiDAR system may lack wavelength stability of the laser light. For instance, the wavelength of the laser light provided by a VCSEL diode laser may drift if ambient environmental changes, such as temperature fluctuations.

To achieve a better LiDAR performance, engineers are pursuing a more sensitive NIR photo detector in a LiDAR system. As a result, one associated challenge is that the detector is more volatile to background noise, such as sunlight. One approach uses spectral filters to block the background noise from reaching the detector. In such cases, the spectral filers have a relatively large bandwidth to cover a whole range of laser spectrum, including instantaneous linewidth and wavelength shifts due to temperature fluctuations. A passband of the filter also has an angle of incidence (AOI) dependency, which leads to a broader passband requirement. LiDAR systems are often used in a moveable platform, such as a vehicle, a plane, a drone, a train, a bicycle, etc. If a LiDAR system is mounted to a vehicle, it may be exposed to a wide temperature fluctuation range, e.g., −40° C. to 95° C. The wavelength drifts corresponding to this wide range of temperature fluctuation can be 20 nm or more. Therefore, to accommodate wavelength drifts of 20 nm or more, the spectral filter needs to be a bandpass filter having a typical bandwidth of about 50 nm. For a small wavelength drift, a bandwidth of at least 20-30 nm is needed. A large bandwidth spectral filter is often undesired because it causes higher background noises and lower signal-to-noise ratio. For instance, a large bandwidth filter may block a high number of light signals before they can reach the detector, thereby reducing the amount of light that can be detected by the light detector. The large bandwidth filter may also allow passing of undesired noise or interference signals. In turn, it reduces the signal-to-noise ratio and the detection performance of the LiDAR system. Furthermore, temperature fluctuations may have different effects on different laser sources. Even for laser sources that are of the same type of semiconductor-based laser used in LiDAR systems, the laser light from different laser sources of the same type may still have about 8 nm random wavelength variations. The random wavelength variations cannot be addressed by using spectral filters such that all the laser sources are calibrated to have a same operational wavelength. Therefore, this is a need to stabilize the operational wavelength of the laser light such that it is substantially temperature independent.

One way to mitigate the wavelength variation problem is to add a cooling system to the laser source to maintain a stable temperature. However, when the LiDAR system is used in a moveable platform, it is energy consuming and technically challenging to add a cooling system to stabilize the temperature to be within an acceptable range so that it does not cause much wavelength shifting. In addition, there may not be enough physical space to isolate the laser source of the LiDAR system by installing a bulky cooling system in a vehicle.

Embodiments discussed herein improve wavelength stability of laser sources by converting certain surface area from a flat or curved surface into periodic grating structures to add spectral selective optical feedback. This results in a broad area diode laser operating at a wavelength predetermined by the grating structure and grating placement, which removes or reduces the wavelength's temperature dependence. As a result, a bandpass filter having a narrower passband can be applied to filter out more background noise, interference signals, or any other undesired signals. A narrowband filter improves the quality of the signals reaching the downstream detector(s) of the LiDAR system, thereby improving the overall detection accuracy of LiDAR system.

Embodiments of present invention are described below. In various embodiments of the present invention, a system for reducing or eliminating wavelength variations of laser light is provided. The system comprises a semiconductor-based laser source emitting laser light, an optical scanner, and one or more optical elements disposed between the laser source and the optical scanner. The optical scanner is configured to direct the laser light to a field-of-view. The one or more optical elements are configured to direct the laser light from the laser source to the optical scanner. The system further comprises a grating structure mounted to, or integrated with, an optical element of the one or more optical elements. One or more characteristics of the grating structure are configured to reduce or eliminate wavelength variations of the laser light caused by variations of one or more operational conditions of the laser source.

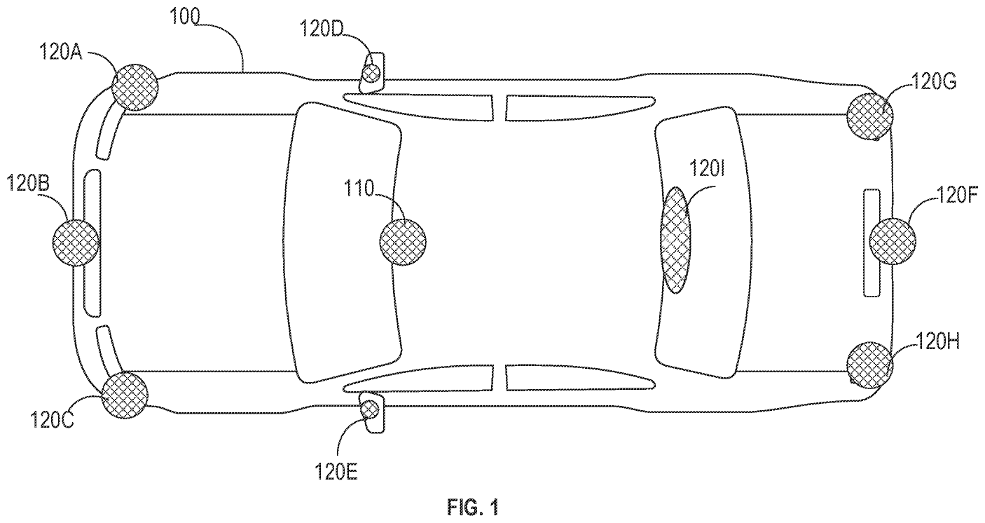

FIG. 1 illustrates one or more example LiDAR systems 110 and 120A-120I disposed or included in a motor vehicle 100. Vehicle 100 can be a car, a sport utility vehicle (SUV), a truck, a train, a wagon, a bicycle, a motorcycle, a tricycle, a bus, a mobility scooter, a tram, a ship, a boat, an underwater vehicle, an airplane, a helicopter, an unmanned aviation vehicle (UAV), a spacecraft, etc. Motor vehicle 100 can be a vehicle having any automated level. For example, motor vehicle 100 can be a partially automated vehicle, a highly automated vehicle, a fully automated vehicle, or a driverless vehicle. A partially automated vehicle can perform some driving functions without a human driver's intervention. For example, a partially automated vehicle can perform blind-spot monitoring, lane keeping and/or lane changing operations, automated emergency braking, smart cruising and/or traffic following, or the like. Certain operations of a partially automated vehicle may be limited to specific applications or driving scenarios (e.g., limited to only freeway driving). A highly automated vehicle can generally perform all operations of a partially automated vehicle but with less limitations. A highly automated vehicle can also detect its own limits in operating the vehicle and ask the driver to take over the control of the vehicle when necessary. A fully automated vehicle can perform all vehicle operations without a driver's intervention but can also detect its own limits and ask the driver to take over when necessary. A driverless vehicle can operate on its own without any driver intervention.

In typical configurations, motor vehicle 100 comprises one or more LiDAR systems 110 and 120A-120I. Each of LiDAR systems 110 and 120A-120I can be a scanning-based LiDAR system and/or a non-scanning LiDAR system (e.g., a flash LiDAR). A scanning-based LiDAR system scans one or more light beams in one or more directions (e.g., horizontal and vertical directions) to detect objects in a field-of-view (FOV). A non-scanning based LiDAR system transmits laser light to illuminate an FOV without scanning. For example, a flash LiDAR is a type of non-scanning based LiDAR system. A flash LiDAR can transmit laser light to simultaneously illuminate an FOV using a single light pulse or light shot.

A LiDAR system is a frequently-used sensor of a vehicle that is at least partially automated. In one embodiment, as shown in FIG. 1, motor vehicle 100 may include a single LiDAR system 110 (e.g., without LiDAR systems 120A-120I) disposed at the highest position of the vehicle (e.g., at the vehicle roof). Disposing LiDAR system 110 at the vehicle roof facilitates a 360-degree scanning around vehicle 100. In some other embodiments, motor vehicle 100 can include multiple LiDAR systems, including two or more of systems 110 and/or 120A-120I. As shown in FIG. 1, in one embodiment, multiple LiDAR systems 110 and/or 120A-120I are attached to vehicle 100 at different locations of the vehicle. For example, LiDAR system 120A is attached to vehicle 100 at the front right corner; LiDAR system 120B is attached to vehicle 100 at the front center position; LiDAR system 120C is attached to vehicle 100 at the front left corner; LiDAR system 120D is attached to vehicle 100 at the right-side rear view mirror; LiDAR system 120E is attached to vehicle 100 at the left-side rear view mirror; LiDAR system 120F is attached to vehicle 100 at the back center position; LiDAR system 120G is attached to vehicle 100 at the back right corner; LiDAR system 120H is attached to vehicle 100 at the back left corner; and/or LiDAR system 120I is attached to vehicle 100 at the center towards the backend (e.g., back end of the vehicle roof). It is understood that one or more LiDAR systems can be distributed and attached to a vehicle in any desired manner and FIG. 1 only illustrates one embodiment. As another example, LiDAR systems 120D and 120E may be attached to the B-pillars of vehicle 100 instead of the rear-view mirrors. As another example, LiDAR system 120B may be attached to the windshield of vehicle 100 instead of the front bumper.

In some embodiments, LiDAR systems 110 and 120A-120I are independent LiDAR systems having their own respective laser sources, control electronics, transmitters, receivers, and/or steering mechanisms. In other embodiments, some of LiDAR systems 110 and 120A-120I can share one or more components, thereby forming a distributed sensor system. In one example, optical fibers are used to deliver laser light from a centralized laser source to all LiDAR systems. For instance, system 110 (or another system that is centrally positioned or positioned anywhere inside the vehicle 100) includes a light source, a transmitter, and a light detector, but has no steering mechanisms. System 110 may distribute transmission light to each of systems 120A-120I. The transmission light may be distributed via optical fibers. Optical connectors can be used to couple the optical fibers to each of system 110 and 120A-120I. In some examples, one or more of systems 120A-120I include steering mechanisms but no light sources, transmitters, or light detectors. A steering mechanism may include one or more moveable mirrors such as one or more polygon mirrors, one or more single plane mirrors, one or more multi-plane mirrors, or the like. Embodiments of the light source, transmitter, steering mechanism, and light detector are described in more detail below. Via the steering mechanisms, one or more of systems 120A-120I scan light into one or more respective FOVs and receive corresponding return light. The return light is formed by scattering or reflecting the transmission light by one or more objects in the FOVs. Systems 120A-120I may also include collection lens and/or other optics to focus and/or direct the return light into optical fibers, which deliver the received return light to system 110. System 110 includes one or more light detectors for detecting the received return light. In some examples, system 110 is disposed inside a vehicle such that it is in a temperature-controlled environment, while one or more systems 120A-120I may be at least partially exposed to the external environment.

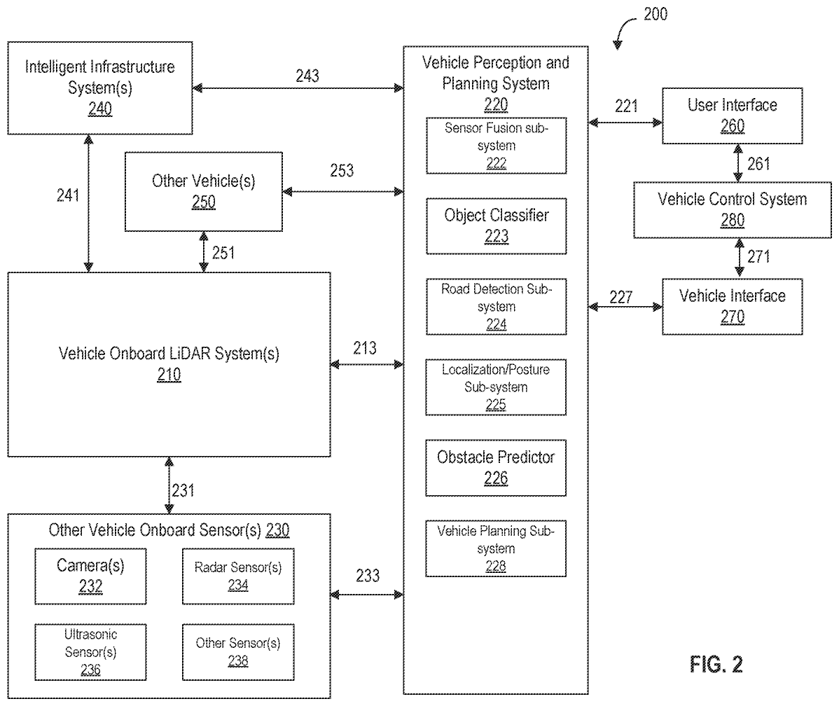

FIG. 2 is a block diagram 200 illustrating interactions between vehicle onboard LiDAR system(s) 210 and multiple other systems including a vehicle perception and planning system 220. LiDAR system(s) 210 can be mounted on or integrated to a vehicle. LiDAR system(s) 210 include sensor(s) that scan laser light to the surrounding environment to measure the distance, angle, and/or velocity of objects. Based on the scattered light that returned to LiDAR system(s) 210, it can generate sensor data (e.g., image data or 3D point cloud data) representing the perceived external environment.

LiDAR system(s) 210 can include one or more of short-range LiDAR sensors, medium-range LiDAR sensors, and long-range LiDAR sensors. A short-range LiDAR sensor measures objects located up to about 20-50 meters from the LiDAR sensor. Short-range LiDAR sensors can be used for, e.g., monitoring nearby moving objects (e.g., pedestrians crossing street in a school zone), parking assistance applications, or the like. A medium-range LiDAR sensor measures objects located up to about 70-200 meters from the LiDAR sensor. Medium-range LiDAR sensors can be used for, e.g., monitoring road intersections, assistance for merging onto or leaving a freeway, or the like. A long-range LiDAR sensor measures objects located up to about 200 meters and beyond. Long-range LiDAR sensors are typically used when a vehicle is travelling at a high speed (e.g., on a freeway), such that the vehicle's control systems may only have a few seconds (e.g., 6-8 seconds) to respond to any situations detected by the LiDAR sensor. As shown in FIG. 2, in one embodiment, the LiDAR sensor data can be provided to vehicle perception and planning system 220 via a communication path 213 for further processing and controlling the vehicle operations. Communication path 213 can be any wired or wireless communication links that can transfer data.

With reference still to FIG. 2, in some embodiments, other vehicle onboard sensor(s) 230 are configured to provide additional sensor data separately or together with LiDAR system(s) 210. Other vehicle onboard sensors 230 may include, for example, one or more camera(s) 232, one or more radar(s) 234, one or more ultrasonic sensor(s) 236, and/or other sensor(s) 238. Camera(s) 232 can take images and/or videos of the external environment of a vehicle. Camera(s) 232 can take, for example, high-definition (HD) videos having millions of pixels in each frame. A camera includes image sensors that facilitate producing monochrome or color images and videos. Color information may be important in interpreting data for some situations (e.g., interpreting images of traffic lights). Color information may not be available from other sensors such as LiDAR or radar sensors. Camera(s) 232 can include one or more of narrow-focus cameras, wider-focus cameras, side-facing cameras, infrared cameras, fisheye cameras, or the like. The image and/or video data generated by camera(s) 232 can also be provided to vehicle perception and planning system 220 via communication path 233 for further processing and controlling the vehicle operations. Communication path 233 can be any wired or wireless communication links that can transfer data. Camera(s) 232 can be mounted on, or integrated to, a vehicle at any location (e.g., rear-view mirrors, pillars, front grille, and/or back bumpers, etc.).

Other vehicle onboard sensors(s) 230 can also include radar sensor(s) 234. Radar sensor(s) 234 use radio waves to determine the range, angle, and velocity of objects. Radar sensor(s) 234 produce electromagnetic waves in the radio or microwave spectrum. The electromagnetic waves reflect off an object and some of the reflected waves return to the radar sensor, thereby providing information about the object's position and velocity. Radar sensor(s) 234 can include one or more of short-range radar(s), medium-range radar(s), and long-range radar(s). A short-range radar measures objects located at about 0.1-30 meters from the radar. A short-range radar is useful in detecting objects located near the vehicle, such as other vehicles, buildings, walls, pedestrians, bicyclists, etc. A short-range radar can be used to detect a blind spot, assist in lane changing, provide rear-end collision warning, assist in parking, provide emergency braking, or the like. A medium-range radar measures objects located at about 30-80 meters from the radar. A long-range radar measures objects located at about 80-200 meters. Medium- and/or long-range radars can be useful in, for example, traffic following, adaptive cruise control, and/or highway automatic braking. Sensor data generated by radar sensor(s) 234 can also be provided to vehicle perception and planning system 220 via communication path 233 for further processing and controlling the vehicle operations. Radar sensor(s) 234 can be mounted on, or integrated to, a vehicle at any location (e.g., rear-view mirrors, pillars, front grille, and/or back bumpers, etc.).

Other vehicle onboard sensor(s) 230 can also include ultrasonic sensor(s) 236. Ultrasonic sensor(s) 236 use acoustic waves or pulses to measure objects located external to a vehicle. The acoustic waves generated by ultrasonic sensor(s) 236 are transmitted to the surrounding environment. At least some of the transmitted waves are reflected off an object and return to the ultrasonic sensor(s) 236. Based on the return signals, a distance of the object can be calculated. Ultrasonic sensor(s) 236 can be useful in, for example, checking blind spots, identifying parking spaces, providing lane changing assistance into traffic, or the like. Sensor data generated by ultrasonic sensor(s) 236 can also be provided to vehicle perception and planning system 220 via communication path 233 for further processing and controlling the vehicle operations. Ultrasonic sensor(s) 236 can be mount on, or integrated to, a vehicle at any location (e.g., rear-view mirrors, pillars, front grille, and/or back bumpers, etc.).

In some embodiments, one or more other sensor(s) 238 may be attached in a vehicle and may also generate sensor data. Other sensor(s) 238 may include, for example, global positioning systems (GPS), inertial measurement units (IMU), or the like. Sensor data generated by other sensor(s) 238 can also be provided to vehicle perception and planning system 220 via communication path 233 for further processing and controlling the vehicle operations. It is understood that communication path 233 may include one or more communication links to transfer data between the various sensor(s) 230 and vehicle perception and planning system 220.

In some embodiments, as shown in FIG. 2, sensor data from other vehicle onboard sensor(s) 230 can be provided to vehicle onboard LiDAR system(s) 210 via communication path 231. LiDAR system(s) 210 may process the sensor data from other vehicle onboard sensor(s) 230. For example, sensor data from camera(s) 232, radar sensor(s) 234, ultrasonic sensor(s) 236, and/or other sensor(s) 238 may be correlated or fused with sensor data LiDAR system(s) 210, thereby at least partially offloading the sensor fusion process performed by vehicle perception and planning system 220. It is understood that other configurations may also be implemented for transmitting and processing sensor data from the various sensors (e.g., data can be transmitted to a cloud or edge computing service provider for processing and then the processing results can be transmitted back to the vehicle perception and planning system 220 and/or LiDAR system 210).

With reference still to FIG. 2, in some embodiments, sensors onboard other vehicle(s) 250 are used to provide additional sensor data separately or together with LiDAR system(s) 210. For example, two or more nearby vehicles may have their own respective LiDAR sensor(s), camera(s), radar sensor(s), ultrasonic sensor(s), etc. Nearby vehicles can communicate and share sensor data with one another. Communications between vehicles are also referred to as V2V (vehicle to vehicle) communications. For example, as shown in FIG. 2, sensor data generated by other vehicle(s) 250 can be communicated to vehicle perception and planning system 220 and/or vehicle onboard LiDAR system(s) 210, via communication path 253 and/or communication path 251, respectively. Communication paths 253 and 251 can be any wired or wireless communication links that can transfer data.

Sharing sensor data facilitates a better perception of the environment external to the vehicles. For instance, a first vehicle may not sense a pedestrian that is behind a second vehicle but is approaching the first vehicle. The second vehicle may share the sensor data related to this pedestrian with the first vehicle such that the first vehicle can have additional reaction time to avoid collision with the pedestrian. In some embodiments, similar to data generated by sensor(s) 230, data generated by sensors onboard other vehicle(s) 250 may be correlated or fused with sensor data generated by LiDAR system(s) 210 (or with other LiDAR systems located in other vehicles), thereby at least partially offloading the sensor fusion process performed by vehicle perception and planning system 220.

In some embodiments, intelligent infrastructure system(s) 240 are used to provide sensor data separately or together with LiDAR system(s) 210. Certain infrastructures may be configured to communicate with a vehicle to convey information and vice versa. Communications between a vehicle and infrastructures are generally referred to as V2I (vehicle to infrastructure) communications. For example, intelligent infrastructure system(s) 240 may include an intelligent traffic light that can convey its status to an approaching vehicle in a message such as “changing to yellow in 5 seconds.” Intelligent infrastructure system(s) 240 may also include its own LiDAR system mounted near an intersection such that it can convey traffic monitoring information to a vehicle. For example, a left-turning vehicle at an intersection may not have sufficient sensing capabilities because some of its own sensors may be blocked by traffic in the opposite direction. In such a situation, sensors of intelligent infrastructure system(s) 240 can provide useful data to the left-turning vehicle. Such data may include, for example, traffic conditions, information of objects in the direction the vehicle is turning to, traffic light status and predictions, or the like. These sensor data generated by intelligent infrastructure system(s) 240 can be provided to vehicle perception and planning system 220 and/or vehicle onboard LiDAR system(s) 210, via communication paths 243 and/or 241, respectively. Communication paths 243 and/or 241 can include any wired or wireless communication links that can transfer data. For example, sensor data from intelligent infrastructure system(s) 240 may be transmitted to LiDAR system(s) 210 and correlated or fused with sensor data generated by LiDAR system(s) 210, thereby at least partially offloading the sensor fusion process performed by vehicle perception and planning system 220. V2V and V2I communications described above are examples of vehicle-to-X (V2X) communications, where the “X” represents any other devices, systems, sensors, infrastructure, or the like that can share data with a vehicle.

With reference still to FIG. 2, via various communication paths, vehicle perception and planning system 220 receives sensor data from one or more of LiDAR system(s) 210, other vehicle onboard sensor(s) 230, other vehicle(s) 250, and/or intelligent infrastructure system(s) 240. In some embodiments, different types of sensor data are correlated and/or integrated by a sensor fusion sub-system 222. For example, sensor fusion sub-system 222 can generate a 360-degree model using multiple images or videos captured by multiple cameras disposed at different positions of the vehicle. Sensor fusion sub-system 222 obtains sensor data from different types of sensors and uses the combined data to perceive the environment more accurately. For example, a vehicle onboard camera 232 may not capture a clear image because it is facing the sun or a light source (e.g., another vehicle's headlight during nighttime) directly. A LiDAR system 210 may not be affected as much and therefore sensor fusion sub-system 222 can combine sensor data provided by both camera 232 and LiDAR system 210, and use the sensor data provided by LiDAR system 210 to compensate the unclear image captured by camera 232. As another example, in a rainy or foggy weather, a radar sensor 234 may work better than a camera 232 or a LiDAR system 210. Accordingly, sensor fusion sub-system 222 may use sensor data provided by the radar sensor 234 to compensate the sensor data provided by camera 232 or LiDAR system 210.

In other examples, sensor data generated by other vehicle onboard sensor(s) 230 may have a lower resolution (e.g., radar sensor data) and thus may need to be correlated and confirmed by LiDAR system(s) 210, which usually has a higher resolution. For example, a sewage cover (also referred to as a manhole cover) may be detected by radar sensor 234 as an object towards which a vehicle is approaching. Due to the low-resolution nature of radar sensor 234, vehicle perception and planning system 220 may not be able to determine whether the object is an obstacle that the vehicle needs to avoid. High-resolution sensor data generated by LiDAR system(s) 210 thus can be used to correlated and confirm that the object is a sewage cover and causes no harm to the vehicle.

Vehicle perception and planning system 220 further comprises an object classifier 223. Using raw sensor data and/or correlated/fused data provided by sensor fusion sub-system 222, object classifier 223 can use any computer vision techniques to detect and classify the objects and estimate the positions of the objects. In some embodiments, object classifier 223 can use machine-learning based techniques to detect and classify objects. Examples of the machine-learning based techniques include utilizing algorithms such as region-based convolutional neural networks (R-CNN), Fast R-CNN, Faster R-CNN, histogram of oriented gradients (HOG), region-based fully convolutional network (R-FCN), single shot detector (SSD), spatial pyramid pooling (SPP-net), and/or You Only Look Once (Yolo).

Vehicle perception and planning system 220 further comprises a road detection sub-system 224. Road detection sub-system 224 localizes the road and identifies objects and/or markings on the road. For example, based on raw or fused sensor data provided by radar sensor(s) 234, camera(s) 232, and/or LiDAR system(s) 210, road detection sub-system 224 can build a 3D model of the road based on machine-learning techniques (e.g., pattern recognition algorithms for identifying lanes). Using the 3D model of the road, road detection sub-system 224 can identify objects (e.g., obstacles or debris on the road) and/or markings on the road (e.g., lane lines, turning marks, crosswalk marks, or the like).

Vehicle perception and planning system 220 further comprises a localization and vehicle posture sub-system 225. Based on raw or fused sensor data, localization and vehicle posture sub-system 225 can determine position of the vehicle and the vehicle's posture. For example, using sensor data from LiDAR system(s) 210, camera(s) 232, and/or GPS data, localization and vehicle posture sub-system 225 can determine an accurate position of the vehicle on the road and the vehicle's six degrees of freedom (e.g., whether the vehicle is moving forward or backward, up or down, and left or right). In some embodiments, high-definition (HD) maps are used for vehicle localization. HD maps can provide highly detailed, three-dimensional, computerized maps that pinpoint a vehicle's location. For instance, using the HD maps, localization and vehicle posture sub-system 225 can determine precisely the vehicle's current position (e.g., which lane of the road the vehicle is currently in, how close it is to a curb or a sidewalk) and predict vehicle's future positions.

Vehicle perception and planning system 220 further comprises obstacle predictor 226. Objects identified by object classifier 223 can be stationary (e.g., a light pole, a road sign) or dynamic (e.g., a moving pedestrian, bicycle, another car). For moving objects, predicting their moving path or future positions can be important to avoid collision. Obstacle predictor 226 can predict an obstacle trajectory and/or warn the driver or the vehicle planning sub-system 228 about a potential collision. For example, if there is a high likelihood that the obstacle's trajectory intersects with the vehicle's current moving path, obstacle predictor 226 can generate such a warning. Obstacle predictor 226 can use a variety of techniques for making such a prediction. Such techniques include, for example, constant velocity or acceleration models, constant turn rate and velocity/acceleration models, Kalman Filter and Extended Kalman Filter based models, recurrent neural network (RNN) based models, long short-term memory (LSTM) neural network based models, encoder-decoder RNN models, or the like.

With reference still to FIG. 2, in some embodiments, vehicle perception and planning system 220 further comprises vehicle planning sub-system 228. Vehicle planning sub-system 228 can include one or more planners such as a route planner, a driving behaviors planner, and a motion planner. The route planner can plan the route of a vehicle based on the vehicle's current location data, target location data, traffic information, etc. The driving behavior planner adjusts the timing and planned movement based on how other objects might move, using the obstacle prediction results provided by obstacle predictor 226. The motion planner determines the specific operations the vehicle needs to follow. The planning results are then communicated to vehicle control system 280 via vehicle interface 270. The communication can be performed through communication paths 227 and 271, which include any wired or wireless communication links that can transfer data.

Vehicle control system 280 controls the vehicle's steering mechanism, throttle, brake, etc., to operate the vehicle according to the planned route and movement. In some examples, vehicle perception and planning system 220 may further comprise a user interface 260, which provides a user (e.g., a driver) access to vehicle control system 280 to, for example, override or take over control of the vehicle when necessary. User interface 260 may also be separate from vehicle perception and planning system 220. User interface 260 can communicate with vehicle perception and planning system 220, for example, to obtain and display raw or fused sensor data, identified objects, vehicle's location/posture, etc. These displayed data can help a user to better operate the vehicle. User interface 260 can communicate with vehicle perception and planning system 220 and/or vehicle control system 280 via communication paths 221 and 261 respectively, which include any wired or wireless communication links that can transfer data. It is understood that the various systems, sensors, communication links, and interfaces in FIG. 2 can be configured in any desired manner and not limited to the configuration shown in FIG. 2.

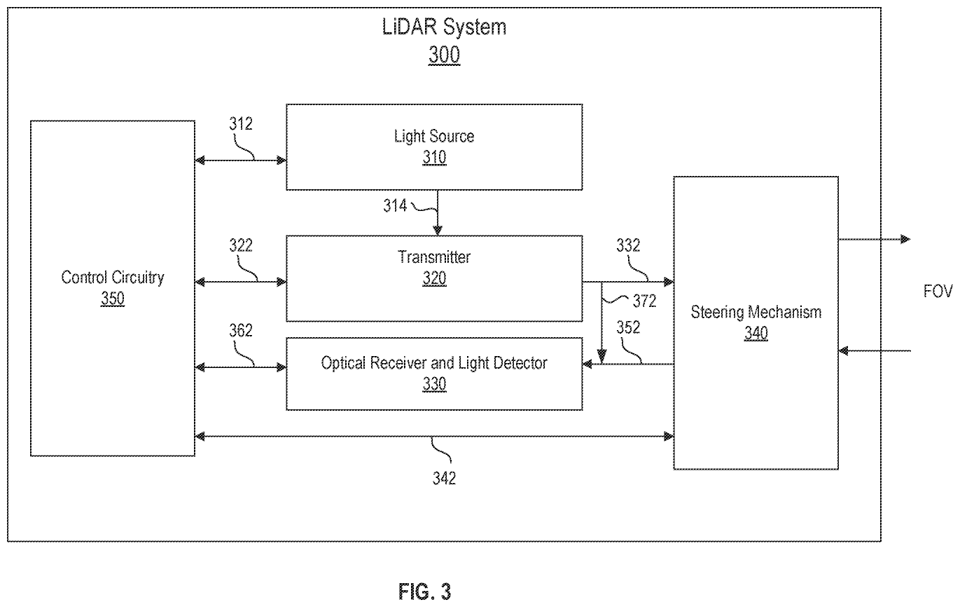

FIG. 3 is a block diagram illustrating an example LiDAR system 300. LiDAR system 300 can be used to implement LiDAR systems 110, 120A-120I, and/or 210 shown in FIGS. 1 and 2. In one embodiment, LiDAR system 300 comprises a light source 310, a transmitter 320, an optical receiver and light detector 330, a steering system 340, and a control circuitry 350. These components are coupled together using communications paths 312, 314, 322, 332, 342, 352, and 362. These communications paths include communication links (wired or wireless, bidirectional or unidirectional) among the various LiDAR system components, but need not be physical components themselves. While the communications paths can be implemented by one or more electrical wires, buses, or optical fibers, the communication paths can also be wireless channels or free-space optical paths so that no physical communication medium is present. For example, in one embodiment of LiDAR system 300, communication path 314 between light source 310 and transmitter 320 may be implemented using one or more optical fibers. Communication paths 332 and 352 may represent optical paths implemented using free space optical components and/or optical fibers. And communication paths 312, 322, 342, and 362 may be implemented using one or more electrical wires that carry electrical signals. The communications paths can also include one or more of the above types of communication mediums (e.g., they can include an optical fiber and a free-space optical component, or include one or more optical fibers and one or more electrical wires).

In some embodiments, LiDAR system 300 can be a coherent LiDAR system. One example is a frequency-modulated continuous-wave (FMCW) LiDAR. Coherent LiDARs detect objects by mixing return light from the objects with light from the coherent laser transmitter. Thus, as shown in FIG. 3, if LiDAR system 300 is a coherent LiDAR, it may include a route 372 providing a portion of transmission light from transmitter 320 to optical receiver and light detector 330. Route 372 may include one or more optics (e.g., optical fibers, lens, mirrors, etc.) for providing the light from transmitter 320 to optical receiver and light detector 330. The transmission light provided by transmitter 320 may be modulated light and can be split into two portions. One portion is transmitted to the FOV, while the second portion is sent to the optical receiver and light detector of the LiDAR system. The second portion is also referred to as the light that is kept local (LO) to the LiDAR system. The transmission light is scattered or reflected by various objects in the FOV and at least a portion of it forms return light. The return light is subsequently detected and interferometrically recombined with the second portion of the transmission light that was kept local. Coherent LiDAR provides a means of optically sensing an object's range as well as its relative velocity along the line-of-sight (LOS).

LiDAR system 300 can also include other components not depicted in FIG. 3, such as power buses, power supplies, LED indicators, switches, etc. Additionally, other communication connections among components may be present, such as a direct connection between light source 310 and optical receiver and light detector 330 to provide a reference signal so that the time from when a light pulse is transmitted until a return light pulse is detected can be accurately measured.

Light source 310 outputs laser light for illuminating objects in a field of view (FOV). The laser light can be infrared light having a wavelength in the range of 700 nm to 1 mm. Light source 310 can be, for example, a semiconductor-based laser (e.g., a diode laser) and/or a fiber-based laser. A semiconductor-based laser can be, for example, an edge emitting laser (EEL), a vertical cavity surface emitting laser (VCSEL), an external-cavity diode laser, a vertical-external-cavity surface-emitting laser, a distributed feedback (DFB) laser, a distributed Bragg reflector (DBR) laser, an interband cascade laser, a quantum cascade laser, a quantum well laser, a double heterostructure laser, or the like. A fiber-based laser is a laser in which the active gain medium is an optical fiber doped with rare-earth elements such as erbium, ytterbium, neodymium, dysprosium, praseodymium, thulium and/or holmium. In some embodiments, a fiber laser is based on double-clad fibers, in which the gain medium forms the core of the fiber surrounded by two layers of cladding. The double-clad fiber allows the core to be pumped with a high-power beam, thereby enabling the laser source to be a high power fiber laser source.

In some embodiments, light source 310 comprises a master oscillator (also referred to as a seed laser) and power amplifier (MOPA). The power amplifier amplifies the output power of the seed laser. The power amplifier can be a fiber amplifier, a bulk amplifier, or a semiconductor optical amplifier. The seed laser can be a diode laser (e.g., a Fabry-Perot cavity laser, a distributed feedback laser), a solid-state bulk laser, or a tunable external-cavity diode laser. In some embodiments, light source 310 can be an optically pumped microchip laser. Microchip lasers are alignment-free monolithic solid-state lasers where the laser crystal is directly contacted with the end mirrors of the laser resonator. A microchip laser is typically pumped with a laser diode (directly or using a fiber) to obtain the desired output power. A microchip laser can be based on neodymium-doped yttrium aluminum garnet (Y₃Al₅O₁₂) laser crystals (i.e., Nd:YAG), or neodymium-doped vanadate (i.e., ND:YVO₄) laser crystals. In some examples, light source 310 may have multiple amplification stages to achieve a high power gain such that the laser output can have high power, thereby enabling the LiDAR system to have a long scanning range. In some examples, the power amplifier of light source 310 can be controlled such that the power gain can be varied to achieve any desired laser output power.

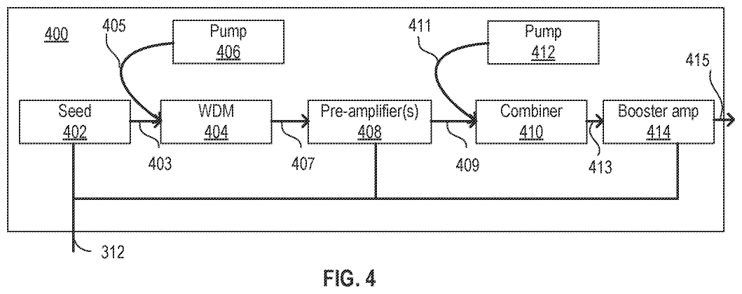

FIG. 4 is a block diagram illustrating an example fiber-based laser source 400 having a seed laser and one or more pumps (e.g., laser diodes) for pumping desired output power. Fiber-based laser source 400 is an example of light source 310 depicted in FIG. 3. In some embodiments, fiber-based laser source 400 comprises a seed laser 402 to generate initial light pulses of one or more wavelengths (e.g., infrared wavelengths such as 1550 nm), which are provided to a wavelength-division multiplexor (WDM) 404 via an optical fiber 403. Fiber-based laser source 400 further comprises a pump 406 for providing laser power (e.g., of a different wavelength, such as 980 nm) to WDM 404 via an optical fiber 405. WDM 404 multiplexes the light pulses provided by seed laser 402 and the laser power provided by pump 406 onto a single optical fiber 407. The output of WDM 404 can then be provided to one or more pre-amplifier(s) 408 via optical fiber 407. Pre-amplifier(s) 408 can be optical amplifier(s) that amplify optical signals (e.g., with about 10-30 dB gain). In some embodiments, pre-amplifier(s) 408 are low noise amplifiers. Pre-amplifier(s) 408 output to an optical combiner 410 via an optical fiber 409. Combiner 410 combines the output laser light of pre-amplifier(s) 408 with the laser power provided by pump 412 via an optical fiber 411. Combiner 410 can combine optical signals having the same wavelength or different wavelengths. One example of a combiner is a WDM. Combiner 410 provides combined optical signals to a booster amplifier 414, which produces output light pulses via optical fiber 415. The booster amplifier 414 provides further amplification of the optical signals (e.g., another 20-40 dB). The output light pulses can then be transmitted to transmitter 320 and/or steering mechanism 340 (shown in FIG. 3). It is understood that FIG. 4 illustrates one example configuration of fiber-based laser source 400. Laser source 400 can have many other configurations using different combinations of one or more components shown in FIG. 4 and/or other components not shown in FIG. 4 (e.g., other components such as power supplies, lens(es), filters, splitters, combiners, etc.).

In some variations, fiber-based laser source 400 can be controlled (e.g., by control circuitry 350) to produce pulses of different amplitudes based on the fiber gain profile of the fiber used in fiber-based laser source 400. Communication path 312 couples fiber-based laser source 400 to control circuitry 350 (shown in FIG. 3) so that components of fiber-based laser source 400 can be controlled by or otherwise communicate with control circuitry 350. Alternatively, fiber-based laser source 400 may include its own dedicated controller. Instead of control circuitry 350 communicating directly with components of fiber-based laser source 400, a dedicated controller of fiber-based laser source 400 communicates with control circuitry 350 and controls and/or communicates with the components of fiber-based laser source 400. Fiber-based laser source 400 can also include other components not shown, such as one or more power connectors, power supplies, and/or power lines.

Referencing FIG. 3, typical operating wavelengths of light source 310 comprise, for example, about 850 nm, about 905 nm, about 940 nm, about 1064 nm, and about 1550 nm. For laser safety, the upper limit of maximum usable laser power is set by the U.S. FDA (U.S. Food and Drug Administration) regulations. The optical power limit at 1550 nm wavelength is much higher than those of the other aforementioned wavelengths. Further, at 1550 nm, the optical power loss in a fiber is low. There characteristics of the 1550 nm wavelength make it more beneficial for long-range LiDAR applications. The amount of optical power output from light source 310 can be characterized by its peak power, average power, pulse energy, and/or the pulse energy density. The peak power is the ratio of pulse energy to the width of the pulse (e.g., full width at half maximum or FWHM). Thus, a smaller pulse width can provide a larger peak power for a fixed amount of pulse energy. A pulse width can be in the range of nanosecond or picosecond. The average power is the product of the energy of the pulse and the pulse repetition rate (PRR). As described in more detail below, the PRR represents the frequency of the pulsed laser light. In general, the smaller the time interval between the pulses, the higher the PRR. The PRR typically corresponds to the maximum range that a LiDAR system can measure. Light source 310 can be configured to produce pulses at high PRR to meet the desired number of data points in a point cloud generated by the LiDAR system. Light source 310 can also be configured to produce pulses at medium or low PRR to meet the desired maximum detection distance. Wall plug efficiency (WPE) is another factor to evaluate the total power consumption, which may be a useful indicator in evaluating the laser efficiency. For example, as shown in FIG. 1, multiple LiDAR systems may be attached to a vehicle, which may be an electrical-powered vehicle or a vehicle otherwise having limited fuel or battery power supply. Therefore, high WPE and intelligent ways to use laser power are often among the important considerations when selecting and configuring light source 310 and/or designing laser delivery systems for vehicle-mounted LiDAR applications.

It is understood that the above descriptions provide non-limiting examples of a light source 310. Light source 310 can be configured to include many other types of light sources (e.g., laser diodes, short-cavity fiber lasers, solid-state lasers, and/or tunable external cavity diode lasers) that are configured to generate one or more light signals at various wavelengths. In some examples, light source 310 comprises amplifiers (e.g., pre-amplifiers and/or booster amplifiers), which can be a doped optical fiber amplifier, a solid-state bulk amplifier, and/or a semiconductor optical amplifier. The amplifiers are configured to receive and amplify light signals with desired gains.

With reference back to FIG. 3, LiDAR system 300 further comprises a transmitter 320. Light source 310 provides laser light (e.g., in the form of a laser beam) to transmitter 320. The laser light provided by light source 310 can be amplified laser light with a predetermined or controlled wavelength, pulse repetition rate, and/or power level. Transmitter 320 receives the laser light from light source 310 and transmits the laser light to steering mechanism 340 with low divergence. In some embodiments, transmitter 320 can include, for example, optical components (e.g., lens, fibers, mirrors, etc.) for transmitting one or more laser beams to a field-of-view (FOV) directly or via steering mechanism 340. While FIG. 3 illustrates transmitter 320 and steering mechanism 340 as separate components, they may be combined or integrated as one system in some embodiments. Steering mechanism 340 is described in more detail below.

Laser beams provided by light source 310 may diverge as they travel to transmitter 320. Therefore, transmitter 320 often comprises a collimating lens configured to collect the diverging laser beams and produce more parallel optical beams with reduced or minimum divergence. The collimated optical beams can then be further directed through various optics such as mirrors and lens. A collimating lens may be, for example, a single plano-convex lens or a lens group. The collimating lens can be configured to achieve any desired properties such as the beam diameter, divergence, numerical aperture, focal length, or the like. A beam propagation ratio or beam quality factor (also referred to as the M² factor) is used for measurement of laser beam quality. In many LiDAR applications, it is important to have good laser beam quality in the generated transmitting laser beam. The M² factor represents a degree of variation of a beam from an ideal Gaussian beam. Thus, the M² factor reflects how well a collimated laser beam can be focused on a small spot, or how well a divergent laser beam can be collimated. Therefore, light source 310 and/or transmitter 320 can be configured to meet, for example, a scan resolution requirement while maintaining the desired M² factor.

One or more of the light beams provided by transmitter 320 are scanned by steering mechanism 340 to a FOV. Steering mechanism 340 scans light beams in multiple dimensions (e.g., in both the horizontal and vertical dimension) to facilitate LiDAR system 300 to map the environment by generating a 3D point cloud. A horizontal dimension can be a dimension that is parallel to the horizon or a surface associated with the LiDAR system or a vehicle (e.g., a road surface). A vertical dimension is perpendicular to the horizontal dimension (i.e., the vertical dimension forms a 90-degree angle with the horizontal dimension). Steering mechanism 340 will be described in more detail below. The laser light scanned to an FOV may be scattered or reflected by an object in the FOV. At least a portion of the scattered or reflected light forms return light that returns to LiDAR system 300. FIG. 3 further illustrates an optical receiver and light detector 330 configured to receive the return light. Optical receiver and light detector 330 comprises an optical receiver that is configured to collect the return light from the FOV. The optical receiver can include optics (e.g., lens, fibers, mirrors, etc.) for receiving, redirecting, focusing, amplifying, and/or filtering return light from the FOV. For example, the optical receiver often includes a collection lens (e.g., a single plano-convex lens or a lens group) to collect and/or focus the collected return light onto a light detector.

A light detector detects the return light focused by the optical receiver and generates current and/or voltage signals proportional to the incident intensity of the return light. Based on such current and/or voltage signals, the depth information of the object in the FOV can be derived. One example method for deriving such depth information is based on the direct TOF (time of flight), which is described in more detail below. A light detector may be characterized by its detection sensitivity, quantum efficiency, detector bandwidth, linearity, signal to noise ratio (SNR), overload resistance, interference immunity, etc. Based on the applications, the light detector can be configured or customized to have any desired characteristics. For example, optical receiver and light detector 330 can be configured such that the light detector has a large dynamic range while having a good linearity. The light detector linearity indicates the detector's capability of maintaining linear relationship between input optical signal power and the detector's output. A detector having good linearity can maintain a linear relationship over a large dynamic input optical signal range.

To achieve desired detector characteristics, configurations or customizations can be made to the light detector's structure and/or the detector's material system. Various detector structures can be used for a light detector. For example, a light detector structure can be a PIN based structure, which has an undoped intrinsic semiconductor region (i.e., an “i” region) between a p-type semiconductor and an n-type semiconductor region. Other light detector structures comprise, for example, an APD (avalanche photodiode) based structure, a PMT (photomultiplier tube) based structure, a SiPM (Silicon photomultiplier) based structure, a SPAD (single-photon avalanche diode) based structure, and/or quantum wires. For material systems used in a light detector, Si, InGaAs, and/or Si/Ge based materials can be used. It is understood that many other detector structures and/or material systems can be used in optical receiver and light detector 330.

A light detector (e.g., an APD based detector) may have an internal gain such that the input signal is amplified when generating an output signal. However, noise may also be amplified due to the light detector's internal gain. Common types of noise include signal shot noise, dark current shot noise, thermal noise, and amplifier noise. In some embodiments, optical receiver and light detector 330 may include a pre-amplifier that is a low noise amplifier (LNA). In some embodiments, the pre-amplifier may also include a transimpedance amplifier (TIA), which converts a current signal to a voltage signal. For a linear detector system, input equivalent noise or noise equivalent power (NEP) measures how sensitive the light detector is to weak signals. Therefore, they can be used as indicators of the overall system performance. For example, the NEP of a light detector specifies the power of the weakest signal that can be detected and therefore it in turn specifies the maximum range of a LiDAR system. It is understood that various light detector optimization techniques can be used to meet the requirement of LiDAR system 300. Such optimization techniques may include selecting different detector structures, materials, and/or implementing signal processing techniques (e.g., filtering, noise reduction, amplification, or the like). For example, in addition to, or instead of, using direct detection of return signals (e.g., by using ToF), coherent detection can also be used for a light detector. Coherent detection allows for detecting amplitude and phase information of the received light by interfering the received light with a local oscillator. Coherent detection can improve detection sensitivity and noise immunity.

FIG. 3 further illustrates that LiDAR system 300 comprises steering mechanism 340. As described above, steering mechanism 340 directs light beams from transmitter 320 to scan an FOV in multiple dimensions. A steering mechanism is referred to as a raster mechanism, a scanning mechanism, or simply a light scanner. Scanning light beams in multiple directions (e.g., in both the horizontal and vertical directions) facilitates a LiDAR system to map the environment by generating an image or a 3D point cloud. A steering mechanism can be based on mechanical scanning and/or solid-state scanning. Mechanical scanning uses rotating mirrors to steer the laser beam or physically rotate the LiDAR transmitter and receiver (collectively referred to as transceiver) to scan the laser beam. Solid-state scanning directs the laser beam to various positions through the FOV without mechanically moving any macroscopic components such as the transceiver. Solid-state scanning mechanisms include, for example, optical phased arrays based steering and flash LiDAR based steering. In some embodiments, because solid-state scanning mechanisms do not physically move macroscopic components, the steering performed by a solid-state scanning mechanism may be referred to as effective steering. A LiDAR system using solid-state scanning may also be referred to as a non-mechanical scanning or simply non-scanning LiDAR system (a flash LiDAR system is an example non-scanning LiDAR system).

Steering mechanism 340 can be used with a transceiver (e.g., transmitter 320 and optical receiver and light detector 330) to scan the FOV for generating an image or a 3D point cloud. As an example, to implement steering mechanism 340, a two-dimensional mechanical scanner can be used with a single-point or several single-point transceivers. A single-point transceiver transmits a single light beam or a small number of light beams (e.g., 2-8 beams) to the steering mechanism. A two-dimensional mechanical steering mechanism comprises, for example, polygon mirror(s), oscillating mirror(s), rotating prism(s), rotating tilt mirror surface(s), single-plane or multi-plane mirror(s), or a combination thereof. In some embodiments, steering mechanism 340 may include non-mechanical steering mechanism(s) such as solid-state steering mechanism(s). For example, steering mechanism 340 can be based on tuning wavelength of the laser light combined with refraction effect, and/or based on reconfigurable grating/phase array. In some embodiments, steering mechanism 340 can use a single scanning device to achieve two-dimensional scanning or multiple scanning devices combined to realize two-dimensional scanning.

As another example, to implement steering mechanism 340, a one-dimensional mechanical scanner can be used with an array or a large number of single-point transceivers. Specifically, the transceiver array can be mounted on a rotating platform to achieve 360-degree horizontal field of view. Alternatively, a static transceiver array can be combined with the one-dimensional mechanical scanner. A one-dimensional mechanical scanner comprises polygon mirror(s), oscillating mirror(s), rotating prism(s), rotating tilt mirror surface(s), or a combination thereof, for obtaining a forward-looking horizontal field of view. Steering mechanisms using mechanical scanners can provide robustness and reliability in high volume production for automotive applications.

As another example, to implement steering mechanism 340, a two-dimensional transceiver can be used to generate a scan image or a 3D point cloud directly. In some embodiments, a stitching or micro shift method can be used to improve the resolution of the scan image or the field of view being scanned. For example, using a two-dimensional transceiver, signals generated at one direction (e.g., the horizontal direction) and signals generated at the other direction (e.g., the vertical direction) may be integrated, interleaved, and/or matched to generate a higher or full resolution image or 3D point cloud representing the scanned FOV.

Some implementations of steering mechanism 340 comprise one or more optical redirection elements (e.g., mirrors or lenses) that steer return light signals (e.g., by rotating, vibrating, or directing) along a receive path to direct the return light signals to optical receiver and light detector 330. The optical redirection elements that direct light signals along the transmitting and receiving paths may be the same components (e.g., shared), separate components (e.g., dedicated), and/or a combination of shared and separate components. This means that in some cases the transmitting and receiving paths are different although they may partially overlap (or in some cases, substantially overlap or completely overlap).

With reference still to FIG. 3, LiDAR system 300 further comprises control circuitry 350. Control circuitry 350 can be configured and/or programmed to control various parts of the LiDAR system 300 and/or to perform signal processing. In a typical system, control circuitry 350 can be configured and/or programmed to perform one or more control operations including, for example, controlling light source 310 to obtain the desired laser pulse timing, the pulse repetition rate, and power; controlling steering mechanism 340 (e.g., controlling the speed, direction, and/or other parameters) to scan the FOV and maintain pixel registration and/or alignment; controlling optical receiver and light detector 330 (e.g., controlling the sensitivity, noise reduction, filtering, and/or other parameters) such that it is an optimal state; and monitoring overall system health/status for functional safety (e.g., monitoring the laser output power and/or the steering mechanism operating status for safety).

Control circuitry 350 can also be configured and/or programmed to perform signal processing to the raw data generated by optical receiver and light detector 330 to derive distance and reflectance information, and perform data packaging and communication to vehicle perception and planning system 220 (shown in FIG. 2). For example, control circuitry 350 determines the time it takes from transmitting a light pulse until a corresponding return light pulse is received; determines when a return light pulse is not received for a transmitted light pulse; determines the direction (e.g., horizontal and/or vertical information) for a transmitted/return light pulse; determines the estimated range in a particular direction; derives the reflectivity of an object in the FOV, and/or determines any other type of data relevant to LiDAR system 300.

LiDAR system 300 can be disposed in a vehicle, which may operate in many different environments including hot or cold weather, rough road conditions that may cause intense vibration, high or low humidities, dusty areas, etc. Therefore, in some embodiments, optical and/or electronic components of LiDAR system 300 (e.g., optics in transmitter 320, optical receiver and light detector 330, and steering mechanism 340) are disposed and/or configured in such a manner to maintain long term mechanical and optical stability. For example, components in LiDAR system 300 may be secured and sealed such that they can operate under all conditions a vehicle may encounter. As an example, an anti-moisture coating and/or hermetic sealing may be applied to optical components of transmitter 320, optical receiver and light detector 330, and steering mechanism 340 (and other components that are susceptible to moisture). As another example, housing(s), enclosure(s), fairing(s), and/or window can be used in LiDAR system 300 for providing desired characteristics such as hardness, ingress protection (IP) rating, self-cleaning capability, resistance to chemical and resistance to impact, or the like. In addition, efficient and economical methodologies for assembling LiDAR system 300 may be used to meet the LiDAR operating requirements while keeping the cost low.

It is understood by a person of ordinary skill in the art that FIG. 3 and the above descriptions are for illustrative purposes only, and a LiDAR system can include other functional units, blocks, or segments, and can include variations or combinations of these above functional units, blocks, or segments. For example, LiDAR system 300 can also include other components not depicted in FIG. 3, such as power buses, power supplies, LED indicators, switches, etc. Additionally, other connections among components may be present, such as a direct connection between light source 310 and optical receiver and light detector 330 so that light detector 330 can accurately measure the time from when light source 310 transmits a light pulse until light detector 330 detects a return light pulse.

These components shown in FIG. 3 are coupled together using communications paths 312, 314, 322, 332, 342, 352, and 362. These communications paths represent communication (bidirectional or unidirectional) among the various LiDAR system components but need not be physical components themselves. While the communications paths can be implemented by one or more electrical wires, buses, or optical fibers, the communication paths can also be wireless channels or open-air optical paths so that no physical communication medium is present. For example, in one example LiDAR system, communication path 314 includes one or more optical fibers; communication path 352 represents an optical path; and communication paths 312, 322, 342, and 362 are all electrical wires that carry electrical signals. The communication paths can also include more than one of the above types of communication mediums (e.g., they can include an optical fiber and an optical path, or one or more optical fibers and one or more electrical wires).

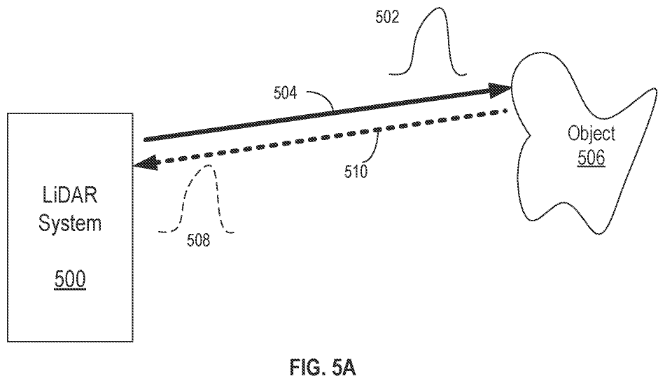

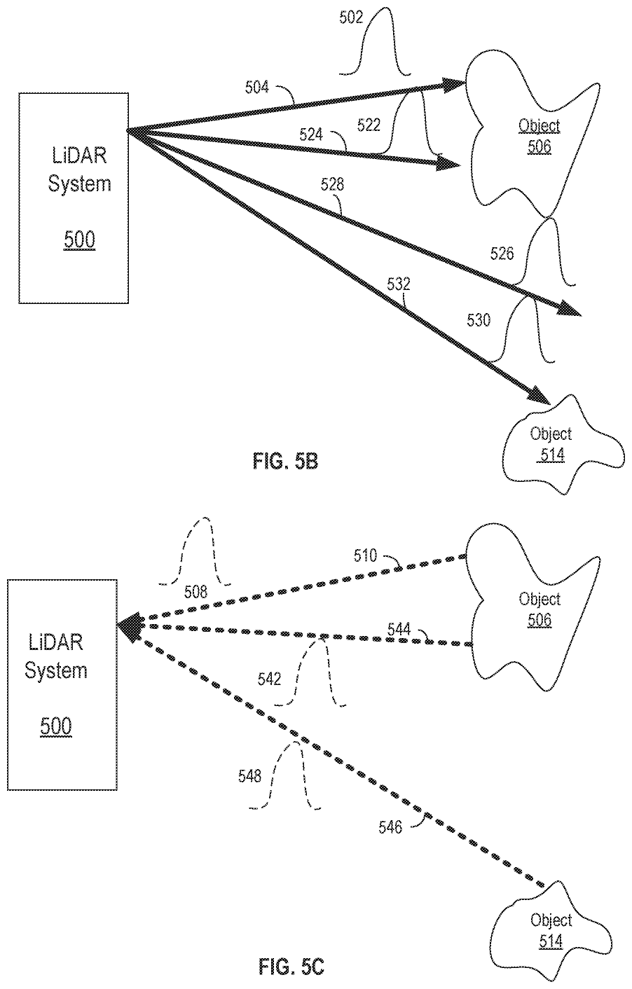

As described above, some LiDAR systems use the time-of-flight (ToF) of light signals (e.g., light pulses) to determine the distance to objects in a light path. For example, with reference to FIG. 5A, an example LiDAR system 500 includes a laser light source (e.g., a fiber laser), a steering mechanism (e.g., a system of one or more moving mirrors), and a light detector (e.g., a photodetector with one or more optics). LiDAR system 500 can be implemented using, for example, LiDAR system 300 described above. LiDAR system 500 transmits a light pulse 502 along light path 504 as determined by the steering mechanism of LiDAR system 500. In the depicted example, light pulse 502, which is generated by the laser light source, is a short pulse of laser light. Further, the signal steering mechanism of the LiDAR system 500 is a pulsed-signal steering mechanism. However, it should be appreciated that LiDAR systems can operate by generating, transmitting, and detecting light signals that are not pulsed and derive ranges to an object in the surrounding environment using techniques other than time-of-flight. For example, some LiDAR systems use frequency modulated continuous waves (i.e., “FMCW”). It should be further appreciated that any of the techniques described herein with respect to time-of-flight based systems that use pulsed signals also may be applicable to LiDAR systems that do not use one or both of these techniques.

Referring back to FIG. 5A (e.g., illustrating a time-of-flight LiDAR system that uses light pulses), when light pulse 502 reaches object 506, light pulse 502 scatters or reflects to form a return light pulse 508. Return light pulse 508 may return to system 500 along light path 510. The time from when transmitted light pulse 502 leaves LiDAR system 500 to when return light pulse 508 arrives back at LiDAR system 500 can be measured (e.g., by a processor or other electronics, such as control circuitry 350, within the LiDAR system). This time-of-flight combined with the knowledge of the speed of light can be used to determine the range/distance from LiDAR system 500 to the portion of object 506 where light pulse 502 scattered or reflected.

By directing many light pulses, as depicted in FIG. 5B, LiDAR system 500 scans the external environment (e.g., by directing light pulses 502, 522, 526, 530 along light paths 504, 524, 528, 532, respectively). As depicted in FIG. 5C, LiDAR system 500 receives return light pulses 508, 542, 548 (which correspond to transmitted light pulses 502, 522, 530, respectively). Return light pulses 508, 542, and 548 are formed by scattering or reflecting the transmitted light pulses by one of objects 506 and 514. Return light pulses 508, 542, and 548 may return to LiDAR system 500 along light paths 510, 544, and 546, respectively. Based on the direction of the transmitted light pulses (as determined by LiDAR system 500) as well as the calculated range from LiDAR system 500 to the portion of objects that scatter or reflect the light pulses (e.g., the portions of objects 506 and 514), the external environment within the detectable range (e.g., the field of view between path 504 and 532, inclusively) can be precisely mapped or plotted (e.g., by generating a 3D point cloud or images).

If a corresponding light pulse is not received for a particular transmitted light pulse, then LiDAR system 500 may determine that there are no objects within a detectable range of LiDAR system 500 (e.g., an object is beyond the maximum scanning distance of LiDAR system 500). For example, in FIG. 5B, light pulse 526 may not have a corresponding return light pulse (as illustrated in FIG. 5C) because light pulse 526 may not produce a scattering event along its transmission path 528 within the predetermined detection range. LiDAR system 500, or an external system in communication with LiDAR system 500 (e.g., a cloud system or service), can interpret the lack of return light pulse as no object being disposed along light path 528 within the detectable range of LiDAR system 500.

In FIG. 5B, light pulses 502, 522, 526, and 530 can be transmitted in any order, serially, in parallel, or based on other timings with respect to each other. Additionally, while FIG. 5B depicts transmitted light pulses as being directed in one dimension or one plane (e.g., the plane of the paper), LiDAR system 500 can also direct transmitted light pulses along other dimension(s) or plane(s). For example, LiDAR system 500 can also direct transmitted light pulses in a dimension or plane that is perpendicular to the dimension or plane shown in FIG. 5B, thereby forming a 2-dimensional transmission of the light pulses. This 2-dimensional transmission of the light pulses can be point-by-point, line-by-line, all at once, or in some other manner. That is, LiDAR system 500 can be configured to perform a point scan, a line scan, a one-shot without scanning, or a combination thereof. A point cloud or image from a 1-dimensional transmission of light pulses (e.g., a single horizontal line) can generate 2-dimensional data (e.g., (1) data from the horizontal transmission direction and (2) the range or distance to objects). Similarly, a point cloud or image from a 2-dimensional transmission of light pulses can generate 3-dimensional data (e.g., (1) data from the horizontal transmission direction, (2) data from the vertical transmission direction, and (3) the range or distance to objects). In general, a LiDAR system performing an n-dimensional transmission of light pulses generates (n+1) dimensional data. This is because the LiDAR system can measure the depth of an object or the range/distance to the object, which provides the extra dimension of data. Therefore, a 2D scanning by a LiDAR system can generate a 3D point cloud for mapping the external environment of the LiDAR system.

The density of a point cloud refers to the number of measurements (data points) per area performed by the LiDAR system. A point cloud density relates to the LiDAR scanning resolution. Typically, a larger point cloud density, and therefore a higher resolution, is desired at least for the region of interest (ROI). The density of points in a point cloud or image generated by a LiDAR system is equal to the number of pulses divided by the field of view. In some embodiments, the field of view can be fixed. Therefore, to increase the density of points generated by one set of transmission-receiving optics (or transceiver optics), the LiDAR system may need to generate a pulse more frequently. In other words, a light source in the LiDAR system may have a higher pulse repetition rate (PRR). On the other hand, by generating and transmitting pulses more frequently, the farthest distance that the LiDAR system can detect may be limited. For example, if a return signal from a distant object is received after the system transmits the next pulse, the return signals may be detected in a different order than the order in which the corresponding signals are transmitted, thereby causing ambiguity if the system cannot correctly correlate the return signals with the transmitted signals.

To illustrate, consider an example LiDAR system that can transmit laser pulses with a pulse repetition rate between 500 kHz and 1 MHz. Based on the time it takes for a pulse to return to the LiDAR system and to avoid mix-up of return pulses from consecutive pulses in a typical LiDAR design, the farthest distance the LiDAR system can detect may be 300 meters and 150 meters for 500 kHz and 1 MHz, respectively. The density of points of a LiDAR system with 500 kHz repetition rate is half of that with 1 MHz. Thus, this example demonstrates that, if the system cannot correctly correlate return signals that arrive out of order, increasing the repetition rate from 500 kHz to 1 MHz (and thus improving the density of points of the system) may reduce the detection range of the system. Various techniques are used to mitigate the tradeoff between higher PRR and limited detection range. For example, multiple wavelengths can be used for detecting objects in different ranges. Optical and/or signal processing techniques (e.g., pulse encoding techniques) are also used to correlate between transmitted and return light signals.

Various systems, apparatus, and methods described herein may be implemented using digital circuitry, or using one or more computers using well-known computer processors, memory units, storage devices, computer software, and other components. Typically, a computer includes a processor for executing instructions and one or more memories for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

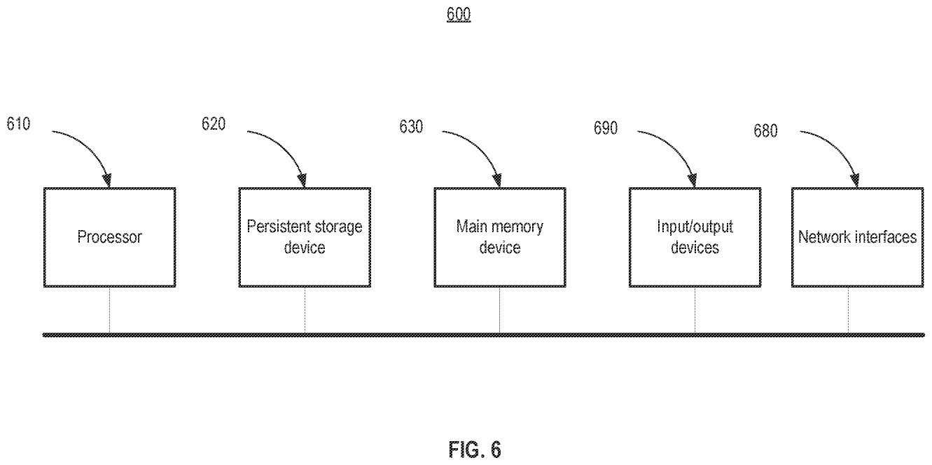

A high-level block diagram of an example apparatus that may be used to implement systems, apparatus and methods described herein is illustrated in FIG. 6. Apparatus 600 comprises a processor 610 operatively coupled to a persistent storage device 620 and a main memory device 630. Processor 610 controls the overall operation of apparatus 600 by executing computer program instructions that define such operations. The computer program instructions may be stored in persistent storage device 620, or other computer-readable medium, and loaded into main memory device 630 when execution of the computer program instructions is desired. For example, processor 610 may be used to implement one or more components and systems described herein, such as control circuitry 350 (shown in FIG. 3), vehicle perception and planning system 220 (shown in FIG. 2), and vehicle control system 280 (shown in FIG. 2). Thus, the methods described herein can be defined by the computer program instructions stored in main memory device 630 and/or persistent storage device 620 and controlled by processor 610 executing the computer program instructions. For example, the computer program instructions can be implemented as computer executable code programmed by one skilled in the art to perform an algorithm defined by the methods described herein. Accordingly, by executing the computer program instructions, the processor 610 executes an algorithm defined by the methods described herein. Apparatus 600 also includes one or more network interfaces 680 for communicating with other devices via a network. Apparatus 600 may also include one or more input/output devices 690 that enable user interaction with apparatus 600 (e.g., display, keyboard, mouse, speakers, buttons, etc.).

Processor 610 may include both general and special purpose microprocessors and may be the sole processor or one of multiple processors of apparatus 600. Processor 610 may comprise one or more central processing units (CPUs), and one or more graphics processing units (GPUs), which, for example, may work separately from and/or multi-task with one or more CPUs to accelerate processing, e.g., for various image processing applications described herein. Processor 610, persistent storage device 620, and/or main memory device 630 may include, be supplemented by, or incorporated in, one or more application-specific integrated circuits (ASICs) and/or one or more field programmable gate arrays (FPGAs).

Persistent storage device 620 and main memory device 630 each comprise a tangible non-transitory computer readable storage medium. Persistent storage device 620, and main memory device 630, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices, semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices.

Input/output devices 690 may include peripherals, such as a printer, scanner, display screen, etc. For example, input/output devices 690 may include a display device such as a cathode ray tube (CRT), plasma or liquid crystal display (LCD) monitor for displaying information to a user, a keyboard, and a pointing device such as a mouse or a trackball by which the user can provide input to apparatus 600.

Any or all of the functions of the systems and apparatuses discussed herein may be performed by processor 610, and/or incorporated in, an apparatus or a system such as LiDAR system 300. Further, LiDAR system 300 and/or apparatus 600 may utilize one or more neural networks or other deep-learning techniques performed by processor 610 or other systems or apparatuses discussed herein.

One skilled in the art will recognize that an implementation of an actual computer or computer system may have other structures and may contain other components as well, and that FIG. 6 is a high-level representation of some of the components of such a computer for illustrative purposes.

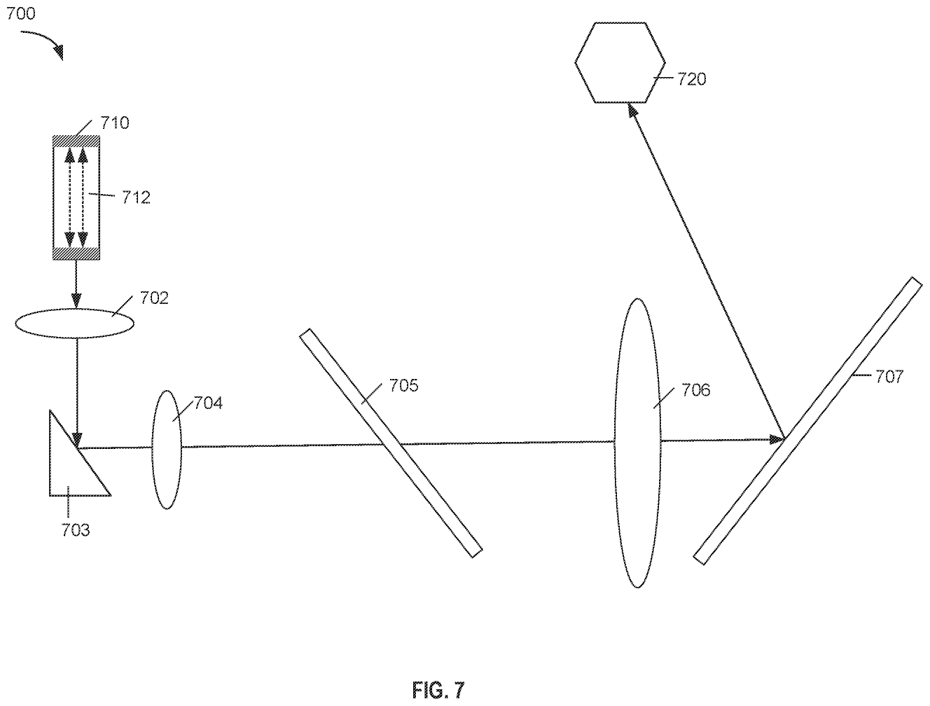

FIG. 7 is a diagram illustrating an exemplary system 700 for providing reduced or eliminated wavelength variations of laser light in a LiDAR system according to an embodiment. The system 700 includes a laser source 710 and an optical scanner 720. The laser source 710 and the optical scanner 720 may be the same or similar to light source 310 and steering mechanism 340, respectively, as described above in FIG. 3. The laser source 710 emits laser light. The optical scanner 720 is configured to direct the laser light to locations within a FOV of the LiDAR system 700. As shown in FIG. 7, the optical scanner 720 can be a polygon mirror.

As shown in FIG. 7, the system 700 further includes one or more optical elements (702-707 shown in FIG. 7) disposed between the laser source 710 and the optical scanner 720. The one or more optical elements are configured to direct the laser light from the laser source 710 to the optical scanner 720. As shown in FIG. 7, in one embodiment, the one or more optical elements comprise a fast-axis collimation (FAC) lens 702, a prism 703, a slow-axis collimation (SAC) lens 704, a combining mirror 705, a lens or lens group 706, and a folding mirror 707. The one or more optical elements 702-707 are disposed in order along an optical path from the laser source 710 to the optical scanner 720.

In the system 700, the laser source 710 is a semiconductor-based laser source emitting laser light. In some embodiments, the semiconductor-based laser source 710 comprises one or more laser diodes. For example, the semiconductor-based laser source 710 comprises one or more of: a vertical-cavity surface-emitting laser (VCSEL), a vertical-external-cavity surface-emitting laser (VECSEL), an external-cavity diode laser, a distributed feedback laser (DFB), a distributed Bragg reflector laser (DBR), a separate confinement heterostructure diode laser, an interband cascade laser, a quantum cascade laser, a quantum well laser, and a double heterostructure laser.

As shown in FIG. 7, the semiconductor-based laser source 710 comprises an internal cavity 712. The internal cavity 712 is an optical cavity surrounding a gain medium. Example gain mediums include crystals (e.g., yttrium aluminum garnet, yttrium orthovanadate, and sapphire), glasses doped with laser-active ions, gases, semiconductors (e.g., gallium arsenide, indium gallium arsenide, and gallium nitride), dye solutions, or the like. In some embodiments, the internal cavity 712 comprises mirrors arranged at two longitudinal ends of the cavity 712 to reflect light beams to form a cavity resonator. As shown in FIG. 7, light beams oscillate many times in the internal cavity 712 before emitting out from the semiconductor-based laser source 710. When the light beams travel through the internal cavity, the gain medium can transfer part of its energy to the light beams, resulting in an increase in optical power for the light beams. As a result, the gain medium can amplify the light beams to form the laser light. The intrinsic wavelength of the laser light is related to a band-gap of semiconductor materials in the semiconductor-based laser source 710. In some embodiments, the semiconductor-based laser source 710 comprises laser emitting devices made from one or more of Gallium Arsenide-based, Indium Phosphide-based, Gallium Antimonide-based, and Gallium Nitride-based materials.

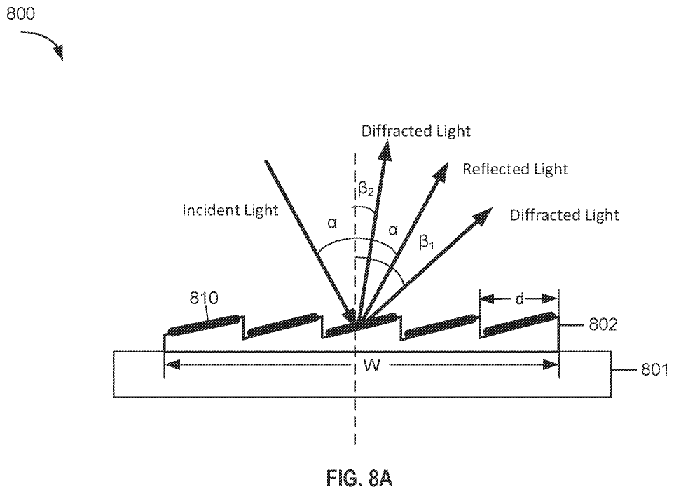

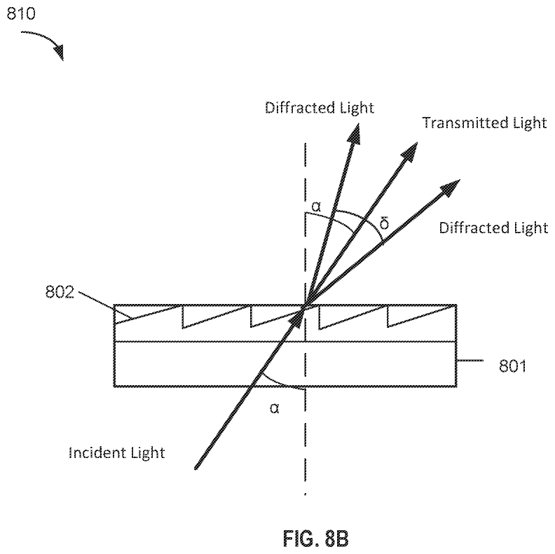

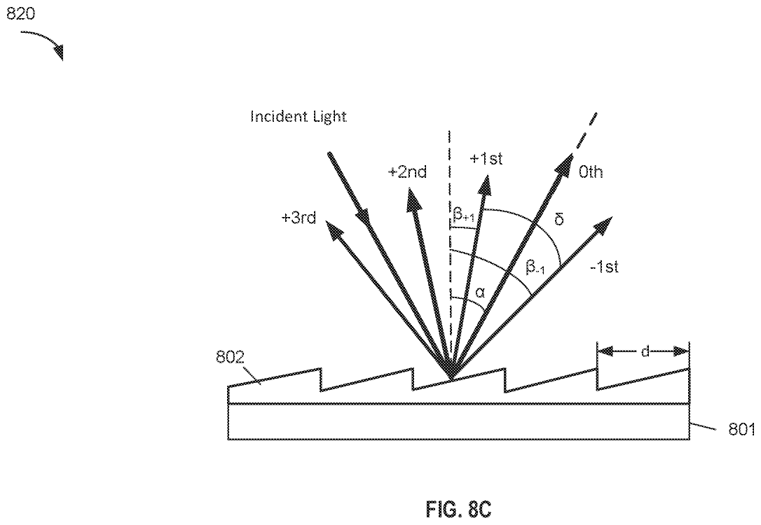

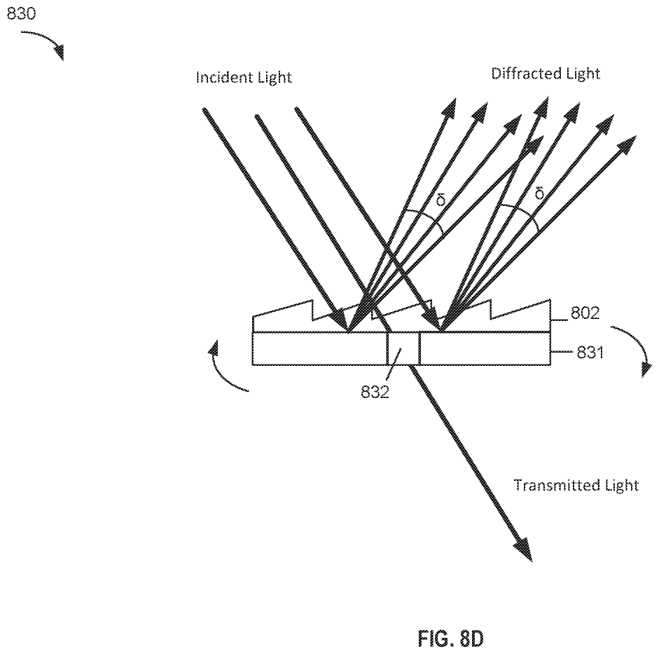

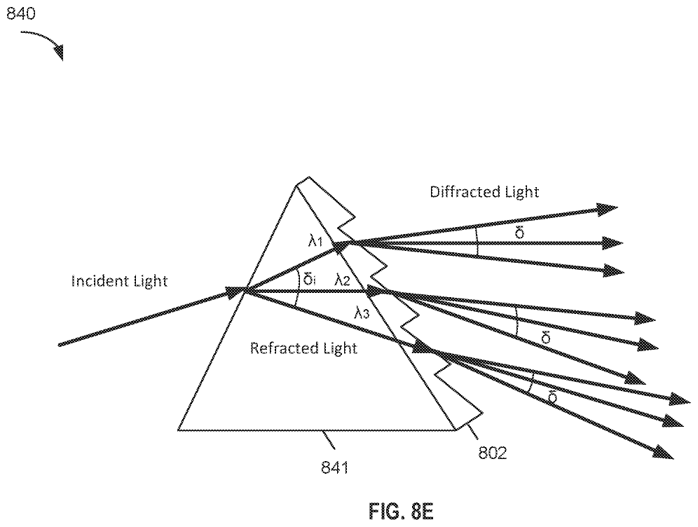

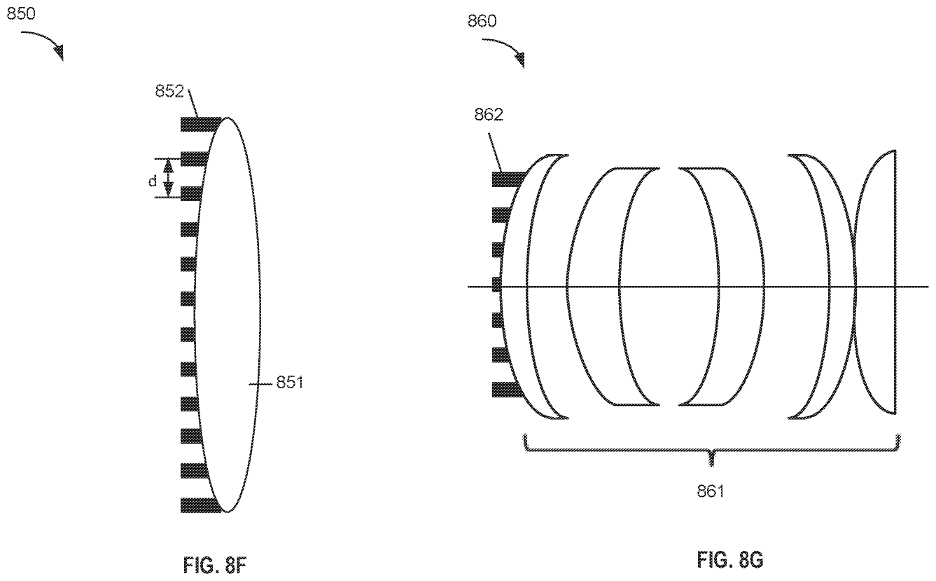

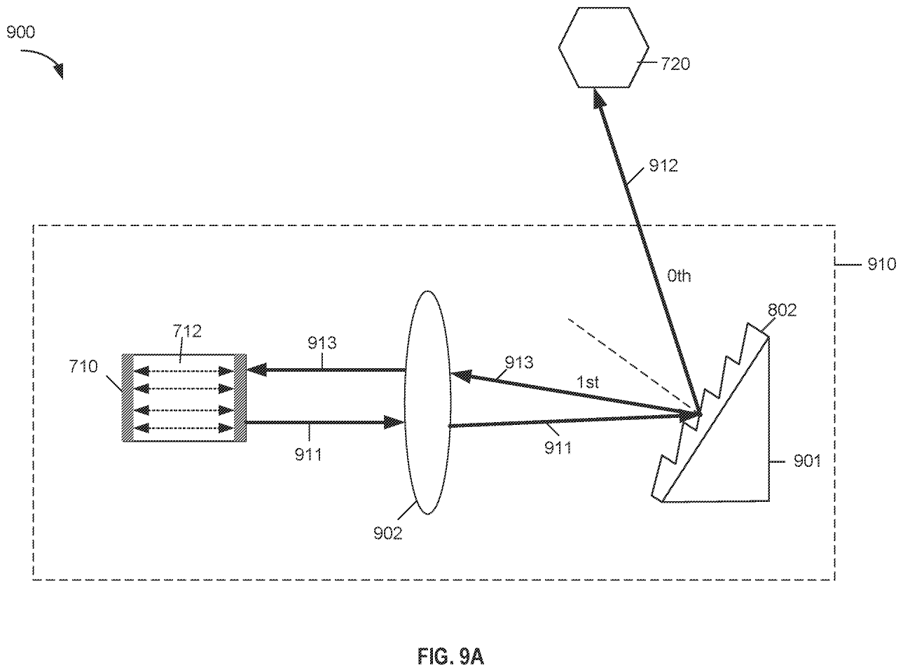

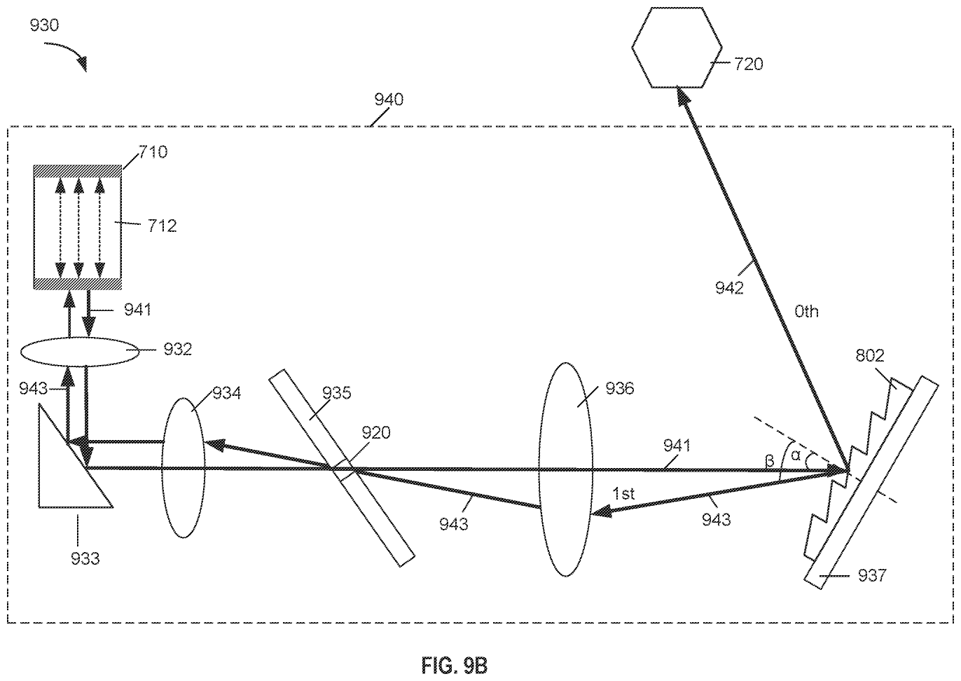

Compared with a fiber-based laser (e.g., laser source 400 shown in FIG. 4), the semiconductor-based laser source 710 has advantages in size, efficiency, and cost. As described above, the semiconductor-based laser source 710 can provide more power than needed in a LiDAR system. The power provided by the semiconductor-based laser source 710 can reach a limit of single-photon for a detector. However, a drawback for the semiconductor-based laser source 710 used in the LiDAR system is that laser light lacks wavelength stability. The wavelength of the laser light emitted from the semiconductor-based laser source 710 shifts due to temperature fluctuations. Especially, the LiDAR system is often used in a moveable platform that can expose the LiDAR system to a wide temperature fluctuation range from, e.g., −40° C. to 95° C. To reduce or eliminate wavelength variations of the laser light caused by variations of one or more operational conditions of the laser source, the system 700 further comprises a grating structure mounted to, or integrated with, an optical element of the one or more optical elements 702-707. This is described in detail further below with reference to FIGS. 8A-8G. The grating structure converts a certain surface area of the one or more optical elements 702-707 into gratings and provides spectral selective feedback to the semiconductor-based laser source 710. This is described in detail further below with reference to FIGS. 9A-9B. As a result, the laser light oscillates in a broad area at a predetermined wavelength. This removes the temperature dependence of wavelength. While FIG. 7 illustrates an example of an optical path comprising optical elements 702-707, it is understood that the optical path from the laser source 720 to scanner 720 can include fewer or more optical elements. One or more of these optical elements can have grating structures for controlling the wavelength stability in a similar manner as described below.

FIGS. 8A-8G are diagrams illustrating examples of grating optics 800-860 and light paths associated with the grating optics 800-860 according to some embodiments. Each of the grating optics 800-860 comprises a grating structure (e.g., grating structure 802 shown in FIGS. 8A-8E and grating structure 852 shown in FIGS. 8F and 8G) mounted to, or integrated with an optical element (e.g., optical element 801 shown in FIGS. 8A-8C, optical element 831 shown in FIG. 8D, optical element 841 shown in FIG. 8E, optical element 851 shown in FIG. 8F, and optical element 861 shown in FIG. 8G). In some embodiments, the optical element can be any of the one or more optical elements 702-707 in the system 700 shown in FIG. 7 (e.g., a lens, a prism, a mirror, etc.). One or more characteristics of the grating structure are configured to reduce or eliminate wavelength variations of the laser light caused by variations of one or more operational conditions of the laser source. As shown in FIGS. 8A-8G, the grating structure comprises a periodic structure that diffracts the laser light into a plurality of light beams having different diffraction angles. The grating structure comprises one or more of: a diffractive grating structure, a reflective grating structure, a transmissive grating structure, and a combination thereof. In some embodiments, the grating structure comprises metasurfaces with sub-wavelength thickness.

FIG. 8A illustrates an example of the grating structure 802 that is mounted to the optical element 801. In some embodiments, the grating structure 802 is integrated with the optical element 801 such that the optical element 801 and the grating structure 802 form an integral piece. As shown in FIG. 8A, the grating structure 802 converts a surface area of optical element 801 from a flat or curved surface (e.g., a surface of a mirror, a prism, or a lens) into a periodic grating structure. As mentioned above, the optical element 801 is one optical element of the one or more optical elements 702-707 in the system 700 shown in FIG. 7. The grating structure 802 comprises one or more characteristics configured to reduce or eliminate wavelength variations of the laser light in the system 700. In some embodiments, the one or more characteristics of the grating structure comprise a grating width, a groove spacing, a groove profile, a reflectivity of a grating structure coating, a diffraction angle, a resolution, an angular dispersion, and dimensions of the grating structure. At least some of these characteristics are described using the below examples.

As shown in FIG. 8A, the grating structure 802 comprises a periodic structure with a plurality of grooves, each of which forms a groove profile. As shown in FIG. 8A, in one example, each of the plurality of grooves has a sawtooth-shaped groove profile. In some embodiments, the groove profile for the grating structure 802 can be square-shaped, triangle-shaped, sawtooth-shaped, wave-shaped, or a combination thereof. A dimension of the grating structure 802 is on the order of millimeters. As shown in FIG. 8A, the grating structure 802 can have a grating width W and a groove spacing d. The plurality of grooves are disposed within the grating width W. For a sawtooth-shaped groove profile, the groove spacing d is the width of each of the plurality of the grooves. A resolution of the grating structure 802 is related to the number of grooves in the grating structure 802. The number of grooves is equal to the grating width W divided by the groove spacing d. The grating structure 802 can comprise 100-10,000 grooves in each millimeter. In some embodiments, the groove spacing d of the grating structure 802 is about 0.0001-0.01 millimeter. As shown in FIG. 8A, the grating structure 802 further comprises a grating structure coating 810. In some embodiments, a reflectivity of the grating structure coating is a characteristic of the grating structure 802 configured to reduce or eliminate wavelength variations of the laser light.

FIG. 8A also illustrates light paths associated with grating optics 800. As shown in FIG. 8A, a laser light beam is directed to the optical element 801 with an AOI α. The AOI α is between the direction of the incident light and the normal direction of the optical element 801 (shown as the dashed line). The normal direction of the optical element 801 is a direction perpendicular to a surface to which the grating structure 802 is mounted. As a result, when receiving the incident light with an AOI of α, the grating structure 802 forms a reflective light beam with an angle of reflection equal to α. The angle of reflection α is between the direction of the reflective light and the normal direction of the optical element 801.

The grating structure 802 shown in FIG. 8A comprises a diffractive grating structure, a reflective grating structure, and a combination thereof. Due to an interaction of the laser light and the grating structure 802, the grating structure 802 diffracts the laser light into a plurality of light beams having different diffraction angles β₁ and β₂. The diffraction angles β₁ and β₂ refer to the angles between the direction of the corresponding diffracted light beam and the normal direction of the optical element 801. Neither β₁ nor β₂ equals to the AOI of α. FIG. 8A only illustrates two diffracted light beams with different diffraction angles β₁ and β₂, but it is understood that more diffracted light beams can be included. This is described in detail further below with reference to FIG. 8C.

FIG. 8B illustrates another example an example grating optics 810 comprising a grating structure 802 being integrated with the optical element 801. As shown in FIG. 8B, the grating structure 802 is embedded in the optical element 801. The grating structure 802 shown in FIG. 8B comprises a diffractive grating structure, a transmissive grating structure, and a combination thereof. As shown in FIG. 8B, a laser light beam is directed to the optical element 801 with an AOI α. A transmitted light beam with an angle of reflection equal to a is also obtained after passing the optical element 801. Similar to the FIG. 8A, the grating structure 802 comprises a periodic structure that diffracts the incident laser light beam into a plurality of diffracted light beams having different diffraction angles. There are two illustrated diffracted light beams shown in FIG. 8B. One diffracted light beam is at the left side of the transmitted light beam. The other diffracted light beam is at the right side of the transmitted light beam. As shown in FIG. 8B, the diffraction angles of the two diffracted light beams are not equal to the AOI of α. An angle subtended between the plurality of light beams is an angular dispersion denoted by δ. The angular dispersion δ is another characteristic of the grating structure 802.

FIG. 8C is a diagram illustrating an example light path associated with the grating optics 820 comprising multiple orders of diffracted light beams. Similar to FIGS. 8A and 8B, the grating optics 820 includes the grating structure 802 is mounted to, or integrated with, the optical element 801. Thus, grating optics 820 shown in FIG. 8C can represent either optics 800 or optics 810 shown in FIG. 8A or 8B. As shown in FIG. 8C, the grating structure 802 comprises a periodic structure that diffracts the incident laser light beam into a plurality of diffracted light beams having different diffraction angles. The different diffraction angles associated with the plurality of the diffracted light beams are defined according to the follow diffraction equation:

$$d ( sin α - sin {β}_{m} ) = m λ \qquad ( 1 )$$

Here, α is the AOI for the incident laser light; βₘ is a diffraction angle representing the angle between the corresponding diffracted light beam and the normal direction of the optical element 801; d is the groove spacing of the grating structure 802; and m is an integer representing the diffraction order.

According to the above diffraction equation, when the diffraction order m is equal to zero, the diffraction angle β₀ is equal to the AOI of α. In this scenario, the diffracted light beam corresponds to a reflected light beam for a reflective grating structure as shown in FIG. 8A, or a transmitted light beam for a transmissive grating structure as shown in FIG. 8B. As shown in FIG. 8C, the zeroth-order beam (0th) corresponds to the reflected light beam. The diffraction order m can be positive or negative. As shown in FIG. 8C, the first order beam (+1st or −1st) corresponds to a diffracted light intensity maxima at a first diffraction angle (β₊₁ or β₋₁). The first order beam can be the positive first order beam (+1st) or a negative first order beam (−1st). The positive first order beam (+1st) and the negative first order beam (−1st) are on both sides of the zeroth-order beam (0th). As shown in FIG. 8C, the angular dispersion δ is an angle subtended between the positive (+1st) and negative (−1st) first order beams. Because the grating structure 802 diffracts the laser light into a plurality of light beams, a light intensity of a diffracted beam is much smaller than that of the incident light. In some embodiment, the first order beam has a light intensity that is about 0.1-1% or 10-30% of the light intensity of the incident laser light. As shown in FIG. 8C, a second order beam (+2nd) and a third order beam (+3rd) illustrate that the diffraction order m can be an integer with an absolute value larger than 1. However, a light intensity of a second order beam is much smaller than that of the first order beam. A light intensity of a third order beam is much smaller than that of the second order beam. Therefore, based on the incident laser light, the grating structure 802 is configured to provide at least a zeroth-order beam and a first order beam. The zeroth-order beam corresponds to direct transmission or specular reflection of the incident laser light beam.

FIG. 8D illustrates another example of grating optics 830 comprising the grating structure 802 integrated with the optical element 831. In one example, as shown in FIG. 8D, the optical element 831 can be a mirror, e.g., combining mirror 705 shown in FIG. 7. Therefore, optical element 831 shown in FIG. 8D is also referred to as a mirror 831. The grating structure 802 is integrated with the mirror 831 such that the mirror 831 and the grating structure 802 form an integral piece. Similar to the FIGS. 8A-8C, the grating structure 802 comprises a periodic structure that diffracts the incident laser light into a plurality of diffracted light beams having different diffraction angles. The plurality of diffracted light beams has an angular dispersion S. In one embodiment, the mirror 831 is moveable. As shown in FIG. 8D, the mirror 831 can move in the directions of the arrows (e.g., rotate or oscillate about an axis). In one embodiment, the mirror 831 is fixed.

As shown in FIG. 8D, in grating optics 830, the mirror 831 comprises a portion 832 that allows a portion of the incident laser light to pass through, thereby forming transmitted light. In some embodiments, the portion 832 comprises a substantially transparent portion, a portion having an anti-reflection coating, an opening, or a combination thereof. In some embodiments, the portion 832 is at a central portion of the mirror 831 for enabling a portion of the incident laser light to pass through. In other embodiments, the portion 832 may be located at other portions of mirror 831. The integral piece 830 may further comprise a high-reflection coating on a surrounding area of the mirror 831 or the grating structure 802 to diffract other portions of the incident laser light to other directions different from the transmitted laser light, thereby forming diffracted light beams.

FIG. 8E illustrates another example of grating optics 840 comprising the grating structure 802 being integrated with an optical element 841. As shown in FIG. 8E, in one example, the optical element 841 is an optical prism, e.g., a prism 703 shown in FIG. 7. Therefore, optical element 841 is also referred to as optical prism 841. The grating structure 802 is integrated with the optical prism 841 such that the optical prism 841 and the grating structure 802 form an integral piece. As shown in FIG. 8E, an incident light comprises light beams with different wavelengths λ₁, λ₂, and λ₃. The optical prism 841 disperses the incident light into a plurality of refracted light beams. An angle subtended between the plurality of refracted light beams is an intrinsic angular dispersion δᵢ of the optical prism 841. Further, the grating structure 802 comprises a periodic structure that diffracts each of the plurality of refracted light beams into a plurality of diffracted light beams. The plurality of diffracted light beams has an angular dispersion δ subtended between the plurality of diffracted light beams.

FIG. 8F illustrates another example of grating optics 850 comprising a grating structure 852 integrated with an optical element 851. In the example shown in FIG. 8F, the optical element 851 is a lens, e.g., a FAC lens 702, a SAC lens 704, or a lens 706 shown in FIG. 7. Therefore, optical element 851 is also referred to as lens 851. Similar to FIGS. 8A-8E, the grating structure 852 converts a surface area of the lens 851 into a periodic grating structure. As shown in FIG. 8F, the grating structure 852 comprises a periodic structure with a plurality of square-shaped or rectangle-shaped grooves having a groove spacing d. Each two grooves are separated with the groove spacing d.

FIG. 8G illustrates another example of grating optics 860 comprising the grating structure 862 integrated with the optical element 861. Grating structure 862 can be substantially the same or similar to grating structure 852 described above. The optical element 861 is a lens group, e.g., a lens group 706 shown in FIG. 7.

As described above, including a grating structure to one or more optical elements along a light path in system 700 can provide spectral selective feedback to the semiconductor-based laser source 710 shown in FIG. 7. The grating structure and the internal cavity of the laser source effectively form a compound cavity. This is illustrated using FIGS. 9A and 9B, which are diagrams showing examples of a system comprising a compound cavity formed by an internal cavity of the laser source and a grating structure. The compound cavity is configured to provide reduced or eliminated wavelength variations of laser light in a LiDAR system.

FIG. 9A illustrates an example of a system 900 comprising a compound cavity 910. Similar to system 700, the system 900 comprises a semiconductor-based laser source 710 and an optical scanner 720. The semiconductor-based laser source 710 comprises an internal cavity 712. The system 900 further includes one or more optical elements 901 and 902 disposed between the laser source 710 and the optical scanner 720. The optical elements 901 and 902 can be implemented using optical elements 801, 831, 841, 851, or 861 described above. One or both optical elements 901 and 902 can be configured to direct the laser light from the laser source 710 to the optical scanner 720.

As shown in FIG. 9A, a grating structure 802 (e.g., grating structure 802 shown in FIGS. 8A-8E) is mounted to, or integrated with, an optical element 901. As mentioned above, the grating structure 802 comprises a periodic structure that diffracts the incident laser light into a plurality of diffracted light beams having different diffraction angles. The semiconductor-based laser source 710 emits laser light 911. Based on the laser light 911, the grating structure 802 is configured to provide at least a zeroth-order (0th) beam 912 and a first order (1st) beam 913. As shown in FIG. 9A, the zeroth-order (0th) beam 912 corresponds to a specular reflection of the incident laser light 911 reflected by the optical element 901. The first order (1st) beam 913 corresponds to a diffracted light intensity maxima at a first order diffraction angle. In some embodiments, the first order beam 913 is the positive first order beam or a negative first order beam.

In the system 900, one or more characteristics of the grating structure 802 are configured such that the first order (1st) beam 913 is directed from the grating structure 802 toward to the laser source 710. In some embodiments, one or more characteristics of the grating structure 802 are configured such that a second order beam (not shown) is directed from the grating structure 802 toward to the laser source 710. The second order beam can be directed toward the laser source as feedback instead of, or in addition to, the first order beam. As described above, the higher order beams have much less light intensity, and therefore, they may be used to fine tune the feedback. As mentioned above in FIGS. 8A-8C, the one or more characteristics of the grating structure comprise a grating width, a groove spacing, a groove profile, a reflectivity of a grating structure coating, a diffraction angle, a resolution, an angular dispersion, and dimensions of the grating structure. As shown in FIG. 9A, the first order (1st) beam 913 is in a direction providing feedback to internal cavity 712 of the laser source 710. As a result, the emitted laser light 911 and the feedback light 913 form a light beam oscillation via the internal cavity 712. The oscillation is caused by the compound cavity 910 comprising the internal cavity of the laser source 712 and the grating structure 802.

The compound cavity 910 determines an operational wavelength of the laser light. The operational wavelength of the laser light is substantially temperature independent. The wavelength selection is determined by the geometry of the grating structure 802, resulting in almost no temperature dependent drift. Compared with a dimension of internal cavity 712 of millimeters, the compound cavity 910 extended a length of the cavity to a dimension on the order centimeters, so that the laser light can oscillate in a broad area at the wavelength controlled by the characteristics of grating structure 802. Therefore, the compound cavity 910 improves the quality of the laser light by providing the spectral selective feedback. In addition, the extended compound cavity 910 also facilitates a more efficient calibration of the operational wavelength of the laser light. Therefore, the technologies described in this disclosure mitigate or solve the problem of lacking wavelength stability for a conventional semiconductor-based laser source. Also, the technologies described in this disclosure can be used to improve wavelength stability for other laser sources comprising an internal cavity. The improved wavelength stability in turn provides an enhanced noise immunity of the LiDAR system.

As shown in FIG. 9A, the zeroth-order (0th) beam 912 is an output beam directed from the compound cavity 910 toward to the optical scanner 720. The first order (1st) beam 913 is the feedback beam provided to the internal cavity 712 of the laser source 710. As mentioned above, because the grating structure 802 can diffract an incident laser light into a plurality of light beams, a light intensity of a diffracted beam, e.g., the first order (1st) beam 913, is much smaller than that of the incident light 911. In some embodiments, a gain medium in the internal cavity 712 may further amplify the feedback beam 913 during the beam oscillation in the internal cavity 712. One or more characteristics of the grating structure 802 are configured such that either the zeroth-order (0th) beam or the first order (1st) beam has a dominating intensity. For example, the first order beam 913 can have a light intensity that is about 0.1-1% or 10-30% of a light intensity of the laser light 911. As a result, the beam with a dominating intensity can be selected as the output beam 912, and the beam with less intensity is selected as the feedback beam 913 to the laser source 710. In some embodiments, similar intensities for light beams between the internal cavity 712 and the compound cavity 910 may lead to unstable chaotic behavior for the beam oscillation in the compound cavity 710.

In some embodiments, the optical element 901 is one of the one or more optical elements 702-702 shown in FIG. 7, and/or other optical elements. These optical elements may comprise a FAC lens, a prism, a SAC lens, a combining mirror, a lens or lens group, and a folding mirror. As shown in FIG. 9A, the optical element 901 is a prism. In one example, the system 900 further includes a lens 902 disposed between the laser source 710 and the optical scanner 720. In some embodiment, the lens is a FAC lens or a SAC lens. Lens 902 can facilitate directing (e.g., focusing) incident light 911 from light source 710 to grating structure 802, and/or directing the feedback beam 913 (e.g., the 1^{st} order or 2^{nd} order diffractive light beams) from the grating structure 802 back to internal cavity 712 of laser source 710. In one example, the grating structure 802 can be formed on lens 902, depending on the overall configuration of the compound cavity and wavelength stability requirements.

FIG. 9B illustrates another example of a system 930 comprising a compound cavity 940 formed by an internal cavity of the laser source 710 and a grating structure 802. Similar to FIG. 9A, the system 930 comprises a semiconductor-based laser source 710 and an optical scanner 720. The semiconductor-based laser source 710 comprises an internal cavity 712. The system 930 further includes one or more optical elements disposed between the laser source 710 and the optical scanner 720. In one example, the one or more optical elements comprise a FAC lens 932, a prism 933, a SAC lens 934, a combining mirror 935, a lens or lens group 936, or a folding mirror 937. As shown in FIG. 9B, a grating structure 802 is mounted to, or integrated with, the folding mirror 937.

As shown in FIG. 9B, the semiconductor-based laser source 710 emits laser light 941. The combining mirror 935 comprises a portion 920 that allows the laser light 941 to pass through. In some embodiments, the portion 920 that allows the laser light 941 to pass through comprises a substantially transparent portion, a portion having an anti-reflection coating, an opening, or a combination thereof. In some embodiments, the portion 920 is at a central portion of the mirror 935 for enabling the laser light 941 to pass through. The combining mirror 935 may further comprise a high-reflection coating on a surrounding area at the surface facing lens 906 to redirect other light to different directions. For example, scanner 720 may receive return light formed based on scattering or reflecting the transmitted laser light by one or more objects in an FOV. The return light may be directed by the scanner 720 to combining mirror 905 (via grating structure 802 and lens 906, or directly). The combining mirror 935 can then redirect the return light to a detector (not shown in FIG. 9B) for detection. In other embodiments, the portion 920 can be located at other places of combining mirror 935.

As shown in FIG. 9B, based on the laser light 941, the grating structure 802 is configured to provide at least a zeroth-order (0^{th}) beam 942 and a first order (1^{st}) beam 943. In some embodiments, the laser light 941 is a collimated light beam. In one example, the AOI α of the emitted laser light 941 is about 30 degrees. The zeroth-order (0^{th}) beam 942 corresponds to specular reflection of the incident laser light 941. The reflection angle for the zeroth-order (0^{th}) beam 942 is equal to the incidence angle α. One or more characteristics of the grating structure 802 are configured such that the first order (1^{st}) beam 943 is directed from the grating structure 802 toward the laser source 710. As shown in FIG. 9B, the diffraction angle R of the first order beam is about 60 degrees. In some embodiments, the grating structure 802 comprise thousands of grooves in each millimeter. In some embodiments, the groove spacing of the grating structure 802 is about 0.0001-0.001 millimeter. In some embodiments, as described above, to ensure the system 900 is stable, the first order beam 943 has a light intensity that is about 0.1-1% or 10-30% of a light intensity of the laser light 941.

In some examples as shown in FIG. 9B, the first order beam 943 is directed from the grating structure 802 toward the internal cavity 712 of laser source 710 via the one or more optical elements along the light path. These optical elements include lens 936, combining mirror 935, lens 934, prism 933, and lens 932. These optical elements can facilitate directing (e.g., focusing) incident light 941 from light source 710 to grating structure 802, and/or directing the feedback beam 943 (e.g., the 1st order or 2nd order diffractive light beams) from the grating structure 802 back to internal cavity 712 of laser source 710. In some embodiments, the portion 920 in the combining mirror 935 also allows the feedback beam 943 to pass through. In some embodiments, the grating structure 802 can be formed on lens 936, combining mirror 935, lens 934, prism 933, lens 932, or a combination thereof, depending on the overall configuration of the compound cavity and wavelength stability requirements. While the above description for FIGS. 9A and 9B use the grating structure 802 as an example, it is understood that other grating structures can be used (e.g., grating structures 852 or 862).

As shown in FIG. 9B, the internal cavity of the laser source 712 and the grating structure 802 form a compound cavity 940. The zeroth-order (0^{th}) beam 942 is an output beam from the compound cavity 940 toward to the optical scanner 720. The first order (1^{st}) beam 943 is the feedback beam to internal cavity of the laser source 712. The compound cavity 940 determines an operational wavelength of the laser light. For instance, the dimension of the light path (e.g., the distance from the laser source 710 to grating structure 802) is much larger than the dimension of internal cavity 712. Thus, the operational wavelength is determined by the dimension of the compound cavity 940 and/or the configuration of the grating structure 802. The operational wavelength of the laser light can thus be substantially temperature independent. The compound cavity 940 improves the quality of the laser light by providing the spectral selective feedback and removing the temperature dependence of wavelength. In addition, the compound cavity 940 also facilitates a more efficient calibration of the operational wavelength of the laser light. Therefore, the technologies described in this disclosure solve or mitigate the problem of lacking wavelength stability for the semiconductor-based laser source 710, thereby achieving a superior noise immunity of the LiDAR system.

In some embodiments, a compound cavity (e.g., compound cavity 910 shown in FIG. 9A and compound cavity 940 shown in FIG. 9B) also improves the laser efficiency and reduces the laser power threshold. Thus, provided with the same input electrical power, the laser source 710 can generate more output laser power. In other words, for generating the same output laser power, the laser source 710 requires less electrical power. Thus, the system has better WPE (wall plug efficiency).

The foregoing specification is to be understood as being in every respect illustrative and exemplary, but not restrictive, and the scope of the invention disclosed herein is not to be determined from the specification, but rather from the claims as interpreted according to the full breadth permitted by the patent laws. It is to be understood that the embodiments shown and described herein are only illustrative of the principles of the present invention and that various modifications may be implemented by those skilled in the art without departing from the scope and spirit of the invention. Those skilled in the art could implement various other feature combinations without departing from the scope and spirit of the invention.

What is claimed is:

1. A system for providing reduced or eliminated wavelength variations of laser light, the system comprising:
a semiconductor-based laser source emitting the laser light;
an optical scanner configured to direct the laser light to a field-of-view;
one or more optical elements disposed between the laser source and the optical scanner, the one or more optical elements being configured to direct the laser light from the laser source to the optical scanner; and
a grating structure mounted to, or integrated with, an optical element of the one or more optical elements, one or more characteristics of the grating structure being configured to reduce or eliminate wavelength variations of the laser light caused by variations of one or more operational conditions of the laser source.

2. The system of claim 1, wherein the semiconductor-based laser source comprises one or more laser diodes.

3. The system of claim 1, wherein the semiconductor-based laser source comprises one or more of a vertical-cavity surface-emitting laser (VCSEL), a vertical-external-cavity surface-emitting laser (VECSEL), an external-cavity diode laser, a distributed feedback laser (DFB), a distributed Bragg reflector laser (DBR), a separate confinement heterostructure diode laser, an interband cascade laser, a quantum cascade laser, a quantum well laser, and a double heterostructure laser.

4. The system of claim 1, wherein the semiconductor-based laser source comprises laser emitting devices made from one or more of Gallium Arsenide-based, Indium Phosphide-based, Gallium Antimonide-based, and Gallium Nitride-based materials.

5. The system of claim 1, wherein the grating structure comprises one or more of a diffractive grating structure, a reflective grating structure, a transmissive grating structure, and a combination thereof.

6. The system of claim 1, wherein the grating structure comprises a periodic structure that diffracts the laser light into a plurality of light beams having different diffraction angles.

7. The system of claim 1, wherein the grating structure is configured to provide, based on the laser light, at least a zeroth-order beam and a first order beam, the zeroth-order beam corresponding to direct transmission or specular reflection of the laser light, the first order beam corresponding to a diffracted light intensity maxima at a first order diffraction angle, and wherein the one or more characteristics of the grating structure are configured such that the first order beam is directed from the grating structure toward to the laser source.

8. The system of claim 7, wherein the one or more characteristics of the grating structure comprise a grating width, a groove spacing, a groove profile, a reflectivity of a grating structure coating, a diffraction angle, a resolution, an angular dispersion, and dimensions of the grating structure.

9. The system of claim 7, wherein an internal cavity of the laser source and the grating structure form a compound cavity that determines an operational wavelength of the laser light, the operational wavelength of the laser light being substantially temperature independent.

10. The system of claim 7, wherein the first order beam is the positive first order beam or a negative first order beam.

11. The system of claim 7, wherein the first order beam has a light intensity that is about 0.1-1% or 10-30% of a light intensity of the laser light.

12. The system of claim 1, wherein the grating structure is integrated with the optical element at a surface of the optical element.

13. The system of claim 1, wherein the optical element is a mirror, and the grating structure is integrated with the mirror such that the mirror and the grating structure form an integral piece.

14. The system of claim 13, wherein the mirror is moveable or fixed.

15. The system of claim 13, wherein the mirror comprises a portion that allows the laser light to pass through.

16. The system of claim 15, wherein the portion that allows the laser light to pass through comprises a substantially transparent portion, a portion having an anti-reflection coating, an opening, or a combination thereof.

17. The system of claim 1, wherein the optical element is an optical prism, and the grating structure is integrated with the optical prism such that the optical prism and the grating structure form an integral piece.

18. The system of claim 1, wherein the one or more optical elements comprise a FAC, a prism, an SAC, a combining mirror, a lens or a lens group, and a folding mirror, wherein the FAC, the prism, the SAC, the combining mirror, the lens or lens group, and the folding mirror are disposed in order along an optical path from the laser source to the optical scanner.

19. The system of claim 1, wherein a geometry of the grating structure is configured based on a selected wavelength of the laser light.

20. The system of claim 1, wherein the grating structure is embedded in the optical element.

21. A light ranging and detection (LiDAR) system for providing reduced or eliminated wavelength variations of laser light, the system comprising:
a semiconductor-based laser source emitting the laser light;
an optical scanner configured to direct the laser light to a field-of-view;
one or more optical elements disposed between the laser source and the optical scanner, the one or more optical elements being configured to direct the laser light from the laser source to the optical scanner; and
a grating structure mounted to, or integrated with, an optical element of the one or more optical elements, one or more characteristics of the grating structure being configured to reduce or eliminate wavelength variations of the laser light caused by variations of one or more operational conditions of the laser source.

22. A vehicle comprising a system for providing reduced or eliminated wavelength variations of laser light, the system comprising:
a semiconductor-based laser source emitting the laser light;
an optical scanner configured to direct the laser light to a field-of-view;
one or more optical elements disposed between the laser source and the optical scanner, the one or more optical elements being configured to direct the laser light from the laser source to the optical scanner; and
a grating structure mounted to, or integrated with, an optical element of the one or more optical elements, one or more characteristics of the grating structure being configured to reduce or eliminate wavelength variations of the laser light caused by variations of one or more operational conditions of the laser source.
